(19) United States
(12) Patent Application Publication
(10) Pub. No.: US 2024/0312779 A1
(43) Pub. Date: Sep. 19, 2024

(54) SEMICONDUCTOR SUBSTRATE MANUFACTURING METHOD, SEMICONDUCTOR SUBSTRATE, AND SEMICONDUCTOR SUBSTRATE MANUFACTURING APPARATUS

(71) Applicant: FILNEX INC., Tokyo (JP)

(72) Inventors: Mitsuhiko OGIHARA, Tokyo (JP); Akihiro HASHIMOTO, Tokyo (JP)

(73) Assignee: Filnex Inc., Tokyo (JP)

(21) Appl. No.: 18/677,887

(22) Filed: May 30, 2024

Related U.S. Application Data
(63) Continuation of application No. PCT/JP2023/004833, filed on Feb. 13, 2023.

(51) Int. Cl. H01L 21/02; H01L 21/67; H01L 29/34

(52) U.S. Cl. CPC H01L 21/02444; H01L 21/02378; H01L 21/02433; H01L 21/67098; H01L 29/34

(57) ABSTRACT

A semiconductor substrate manufacturing method includes the steps of: forming, on a first surface of a first substrate, a plurality of terrace portions arranged in a first direction parallel to a horizontal plane of the first substrate, and a step portion having a predetermined height between two adjacent terrace portions in the first direction; forming a first semiconductor layer such that a part of the step portion is exposed; and vaporizing a portion of Si of the first substrate from a part of the step portion exposed from the first semiconductor layer by performing heat treatment on the first substrate on which the first semiconductor layer is formed, thereby forming a buffer layer having at least one graphene layer in at least a part between the first semiconductor layer and the first substrate.

### CROSS-REFERENCE TO RELATED APPLICATIONS

The present application is a continuation application of International Application number PCT/JP2023/004833, filed on Feb. 13, 2023. The contents of this application are incorporated herein by reference in their entirety.

### BACKGROUND OF THE INVENTION

As a conventional method for manufacturing a semiconductor layer, a method is known for reducing the dislocation density of a group III-V nitride compound semiconductor, on a buffer layer on a base material substrate is known (see, for example, Patent Document 1: Japanese Unexamined Patent Application Publication No. 2020-38968).

According to the manufacturing method described in Patent Document 1, an AlN layer having a thickness that is equal to or less than a critical film thickness is formed on an SiC substrate, which is a base material substrate. Subsequently, graphene is formed on the SiC substrate by heat treatment, after which a GaN layer is grown on the AlN layer.

According to the method for manufacturing a semiconductor layer described in Patent Document 1, an AlN layer with low dislocation density can be formed by forming an AlN layer having a thickness that is equal to or less than a critical film thickness on an SiC substrate. However, achieving uniformity in forming such an AlN layer on the SiC substrate has been difficult. Additionally, achieving uniformity in forming a graphene layer with a large area of 1 square centimeter or more on the SiC substrate, with good reproducibility, has been difficult. Consequently, it has been difficult to form a GaN layer with the necessary large area and small dislocation density for forming a high-quality semiconductor device.

The present disclosure has been made in view of these points, and its object is to enable the formation of a high-quality semiconductor layer with a large area and small dislocation density, which has proven challenging in the conventional art.

### BRIEF SUMMARY OF THE INVENTION

A semiconductor substrate manufacturing method according to a first aspect of the present disclosure includes the steps of: forming, on a first surface of a first substrate formed by cutting out a semiconductor crystal along a plane that is inclined with respect to a horizontal plane orthogonal to a crystal growth direction of the semiconductor crystal containing at least Si and C, a plurality of terrace portions that are surfaces along a first direction parallel to the horizontal plane of the first substrate, and a step portion having a predetermined height and positioned between two adjacent terrace portions in the first direction; depositing a first semiconductor layer having a critical film thickness or more after the terrace portions and the step portion have been formed on the first surface of the first substrate, thereby forming the first semiconductor layer such that a part of the step portion is exposed; and vaporizing a portion of Si of the first substrate from a part of the step portion exposed from the first semiconductor layer by performing heat treatment on the first substrate on which the first semiconductor layer is formed, thereby forming a buffer layer having at least one graphene layer in at least a part between the first semiconductor layer and the first substrate, wherein a predetermined height of the step portion is larger than a critical film thickness of the first semiconductor layer obtained by growing crystals on the first surface of the first substrate.

A second aspect of the present disclosure provides a semiconductor substrate including: a first substrate formed of a semiconductor crystal containing at least Si and C, and including, on a first surface, a plurality of terrace portions that are surfaces along a first direction parallel to a horizontal plane perpendicular to a crystal growth direction of the semiconductor crystal, and a step portion having a predetermined height provided between two adjacent terrace portions in the first direction, a first semiconductor layer formed to have a thickness that is less than a height of the step portion and is equal to or greater than a critical film thickness on the plurality of terrace portions, in at least a part of a surface of the first substrate on which the plurality of terrace portions are formed, and a buffer layer having at least one graphene layer formed in at least a part between the first semiconductor layer and the first substrate, wherein a predetermined height of the step portion is larger than a critical film thickness of the first semiconductor layer obtained by growing crystals on the first surface of the first substrate.

A third aspect of the present disclosure provides a semiconductor substrate manufacturing apparatus including: a first fixing stage that exposes a first surface of a first substrate formed by cutting out a semiconductor crystal containing at least Si and C along a plane that is inclined with respect to a horizontal plane perpendicular to a crystal growth direction of the semiconductor crystal, and fixes thereto a second surface that is on an opposite side from the first surface; an etching apparatus that etches the first surface of the first substrate fixed to the first fixing stage to form a plurality of terrace portions that are surfaces along a first direction parallel to the horizontal plane of the first substrate, and a step portion having a predetermined height and positioned between two adjacent terrace portions in the first direction; a first semiconductor layer forming apparatus for forming a first semiconductor layer having a critical film thickness or more on the first surface of the first substrate; an annealing apparatus for heating the first substrate on which the first semiconductor layer is formed and vaporizing a portion of Si of the first substrate from a part of the step portion exposed from the first semiconductor layer, thereby forming a buffer layer having at least one graphene layer in at least a part between the first semiconductor layer and the first substrate; a first transport path that connects a chamber for housing the first substrate of the first semiconductor layer forming apparatus and a chamber for housing the first substrate of the annealing apparatus; and a control part that controls the first fixing stage, the etching apparatus, the first semiconductor layer forming apparatus, and the annealing apparatus, wherein a substrate transport mechanism is provided in the chamber for housing the first substrate of the first semiconductor layer forming apparatus; the chamber for housing the first substrate of the annealing apparatus; and the first transport path, and the substrate transport mechanism allows the first substrate fixed to the first fixing stage to be movable between the chamber of the first semiconductor layer forming apparatus and the chamber of the annealing apparatus, the etching apparatus is provided inside the first semiconductor layer forming apparatus, the control part at least has a function of controlling steps of: moving the first substrate from the first fixing stage to which the first substrate is fixed; forming the plurality of terrace portions and the step portion on the first substrate; forming the first semiconductor layer such that a part of the step portion is exposed; and forming the buffer layer after the forming the first semiconductor layer, and a predetermined height of the step portion is larger than a critical film thickness of the first semiconductor layer obtained by growing crystals on the first surface of the first substrate.

### BRIEF DESCRIPTION OF THE DRAWINGS

FIG. 1 shows an example of a flow of manufacturing a semiconductor substrate according to the present embodiment.

FIG. 2 shows an example of a first substrate 100 according to the present embodiment.

FIG. 3 shows an example in which etching is performed on the first substrate 100 according to the present embodiment.

FIG. 4 shows an example in which a first semiconductor layer 120 is formed on the surface of the first substrate 100 on which a terrace portion 102 and a step portion 110 are formed according to the present embodiment.

FIG. 5 is a schematic diagram of a substrate cross section obtained by enlarging a cross section of the surface of the first substrate 100 on which the first semiconductor layer 120 of FIG. 4 is formed.

FIG. 6 shows an example in which high-temperature heat treatment is performed on a seed layer growth substrate 140 according to the present embodiment in a high-temperature heating furnace 416.

FIG. 7 shows an example in which the first semiconductor layer 120 is grown by changing its thickness with respect to a height h of the step portion 110 according to the present embodiment.

FIG. 8 is a diagram schematically showing the state after high-temperature heat treatment has been performed on the seed layer growth substrate 140 according to the present embodiment.

FIG. 9 is a diagram schematically showing the state of the surface of the seed layer growth substrate 140 after high-temperature heat treatment has been performed, which is shown in FIG. 8.

FIG. 10 shows an example of crystal-growing a second semiconductor layer 160 on the upper surface of an intermediate layer 150 according to the present embodiment.

FIG. 11A shows a first example of a reflection high-energy electron diffraction image of the first semiconductor layer 120 before high-temperature heat treatment.

FIG. 11B shows a first example of a reflection high-energy electron diffraction image of the surface of the intermediate layer 150 after high-temperature heat treatment.

FIG. 12A shows a second example of a reflection high-energy electron diffraction image of the first semiconductor layer 120 before high-temperature heat treatment.

FIG. 12B shows a second example of a reflection high-energy electron diffraction image of the surface of the intermediate layer 150 formed after high-temperature heat treatment.

FIG. 13 shows an example of a Raman scattering spectrum of the surface of the formed intermediate layer 150.

FIG. 14 shows an example of a surface image obtained by observing the surface of the formed intermediate layer 150, with an atomic force microscope.

FIG. 15 shows an example of a symmetric reflection X-ray rocking curve of the second semiconductor layer 160 that has been formed.

FIG. 16A shows an example of an asymmetric reflection X-ray rocking curve with respect to a [10-11] plane from the formed second semiconductor layer 160.

FIG. 16B shows an example of an asymmetric reflection X-ray rocking curve with respect to a [10-12] plane from the formed second semiconductor layer 160.

FIG. 16C shows an example of an asymmetric reflection X-ray rocking curve with respect to a [10-13] plane from the formed second semiconductor layer 160.

FIG. 16D shows an example of an asymmetric reflection X-ray rocking curve with respect to a [30-32] plane from the formed second semiconductor layer 160.

FIG. 17 shows a Raman scattering spectrum of the formed second semiconductor layer 160.

FIG. 18 shows a configuration example of a composite material substrate 200 according to the present embodiment.

FIG. 19A shows a configuration example of a third substrate 206 and a second substrate 204.

FIG. 19B shows an example in which the composite material substrate 200 is formed by bonding the second substrate 204 to the third substrate 206 and then separating these substrates by a separation region 208.

FIG. 20A shows a configuration example in which the second semiconductor layer 160 according to the present embodiment is separated from the first substrate 100.

FIG. 20B shows a configuration example after the second semiconductor layer 160 according to the present embodiment has been separated from the first substrate 100.

FIG. 21A shows an example in which a reinforcing substrate 350 is bonded to the upper surface of the second semiconductor layer 160 according to the present embodiment.

FIG. 21B shows a first example of a second semiconductor substrate 360 according to the present embodiment.

FIG. 22 shows a second example of the second semiconductor substrate 360 according to the present embodiment.

FIG. 23 shows a configuration example of a first manufacturing apparatus 400 according to the present embodiment.

FIG. 24 shows a configuration example of a second manufacturing apparatus 450 according to the present embodiment.

### DETAILED DESCRIPTION OF THE INVENTION

Hereinafter, the present disclosure will be described through exemplary embodiments, but the following exemplary embodiments do not limit the invention according to the claims, and not all of the combinations of features described in the exemplary embodiments are necessarily essential to the solution means of the invention.

### <Example of a Flow of Manufacturing a Semiconductor Substrate>

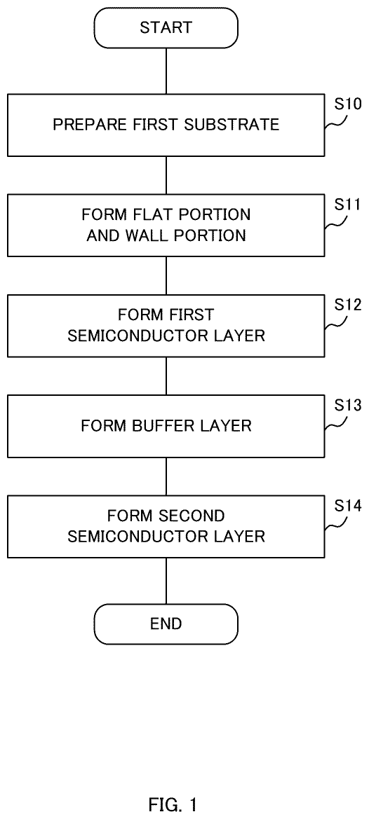

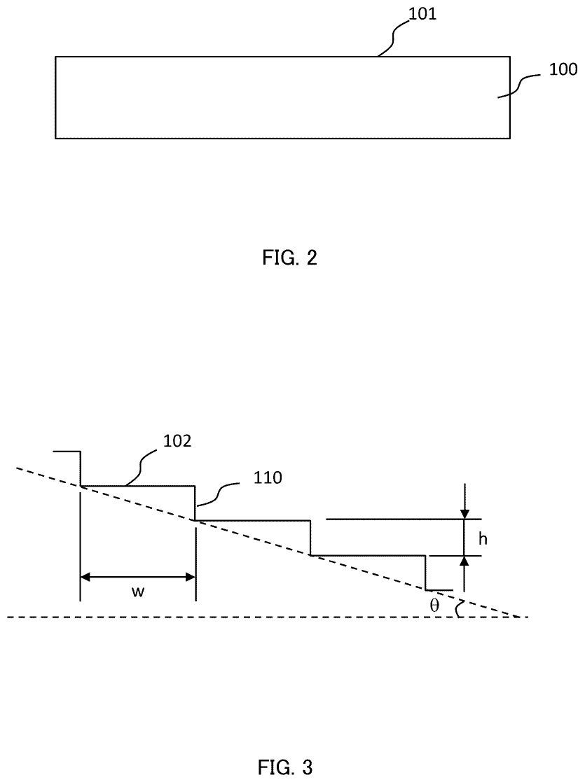

FIG. 1 shows an example of a flow of manufacturing a semiconductor substrate according to the present embodiment. Further, FIGS. 2 to 10 show a process in which the semiconductor substrate is formed by the manufacturing flow.

First, a first substrate 100 serving as a base material is prepared (S10). FIG. 2 shows an example of the first substrate 100 according to the present embodiment. The first substrate 100 is a substrate formed of a semiconductor crystal containing at least Si and C. The semiconductor crystal is preferably a single crystal of SiC. In this embodiment, an example in which an SiC single crystal substrate is used as an example of the first substrate 100 will be described.

The first substrate 100 can be a 4H-SiC single crystal substrate or a 6H-SiC single crystal substrate. The first substrate 100 is a substrate formed by cutting out a semiconductor crystal at a plane that is inclined with respect to a horizontal plane orthogonal to the crystal growth direction of the semiconductor crystal. Here, the horizontal plane orthogonal to the crystal growth direction of the semiconductor crystal is a (0001) plane. As described above, a first surface 101, which is the surface of the first substrate 100, has an orientation (which may be referred to as an off-angle) that is inclined with respect to the exact (0001) plane. Here, an inclination angle with respect to the (0001) plane is defined as θ. The first surface 101 of the first substrate 100 is an Si surface, for example. The first surface 101 may be a C surface that is on the opposite side from the Si surface.

Next, a plurality of flat portions (referred to as a terrace portion in the present embodiment) and one or a plurality of wall portions (referred to as a step portion in the present embodiment) are formed on the first substrate 100 (S11). For example, the first substrate 100 is placed in a furnace capable of heating the substrate to a high temperature in a hydrogen gas atmosphere, and etching is performed on the first surface 101 of the first substrate 100 in a hydrogen (112) atmosphere. When etching the first surface 101, it is desirable to use an etching apparatus capable of setting the substrate temperature to a temperature suitable for substrate surface treatment. The etching apparatus may be an apparatus that is common to a furnace capable of raising the substrate temperature.

The etching apparatus can raise the temperature of the first substrate 100 to 1000° C. or higher, for example. Further, the etching apparatus can set the pressure of hydrogen gas to a pressure suitable for substrate surface treatment, and can set the pressure of the hydrogen gas atmosphere to 1 atm, for example. It should be noted that, etching the first surface 101 of the first substrate 100 may be performed in a mixed gas atmosphere of hydrogen gas and another gas (e.g., argon (Ar) gas, ammonia (NH₃) gas, or the like), in addition to a hydrogen gas atmosphere.

FIG. 3 shows an example in which etching is performed on the first substrate 100 according to the present embodiment. FIG. 3 is a schematic diagram of a substrate cross section obtained by enlarging a cross section of the surface of the first substrate 100 after the etching.

Since the first substrate 100 is formed by growing crystals with the (0001) plane oriented as the horizontal plane of the crystals, the surface of the first substrate 100 is processed such that it forms a plane parallel to the (0001) plane when etching is performed on the first surface 101 that is inclined with respect to the (0001) plane. Since the first surface 101 of the first substrate 100 before etching is inclined with respect to the (0001) plane, a step whose height is controlled to become a predetermined height is formed on the surface of the first substrate 100 by such etching.

FIG. 3 shows an example in which i) a plurality of terrace portions 102 that are arranged in a first direction parallel to the (0001) plane of the first substrate 100 and are surfaces along the first direction, and ii) a step portion 110 having a predetermined height h and positioned between two adjacent terrace portions 102 in the first direction are formed. In FIG. 3, the width of the terrace portion 102 is w. A step height h can be controlled by using the off-angle, off-direction, etching temperature, hydrogen gas flow rate, etching pressure, temperature rise rate, and etching time of the first substrate 100 as control parameters.

It is considered that the step height h is determined by the minimum point of the surface free energy of the first substrate 100, which is dependent on such parameters. In general, it is considered that the step height h of the step portion 110 and the surface morphology of the terrace portions 102 having a width w and sandwiching the step portion 110 are determined by minimizing step-forming energy and surface free energy due to interaction between steps.

When etching the first substrate 100, the etching process is controlled such that the step height h becomes an integer multiple of the lattice constant of the SiC single crystal substrate in a c-axis direction (direction perpendicular to the substrate surface (0001) plane). It should be noted that the lattice constants of a 4H-SiC substrate and a 6H-SiC substrate in the c-axis direction are 1.0 nm and 1.5 nm, respectively. A specific value of the step height h will be described later.

In view of forming a uniform high-quality semiconductor layer on a large-area substrate, it is desirable to control the variation of the step height h of the first substrate 100 to be about ±10 to 20% with respect to the center value of the step height h. As an example, controlling an etching operation of the first substrate 100 makes it possible to set the center value of the step height h in the plane of the first substrate 100 to 60 nm, and set the in-plane variation to ±10 nm.

The terrace width w is determined by the off-angle θ of the first substrate 100. The off-angle θ can be appropriately determined according to the growth condition of the first substrate 100. The practical range of the off-angle θ of the first surface 101 of the first substrate 100 is greater than 0° and smaller than 10°. The off-angle θ may be in the range of 2°<0<6°. The off-angle θ is 4°, for example.

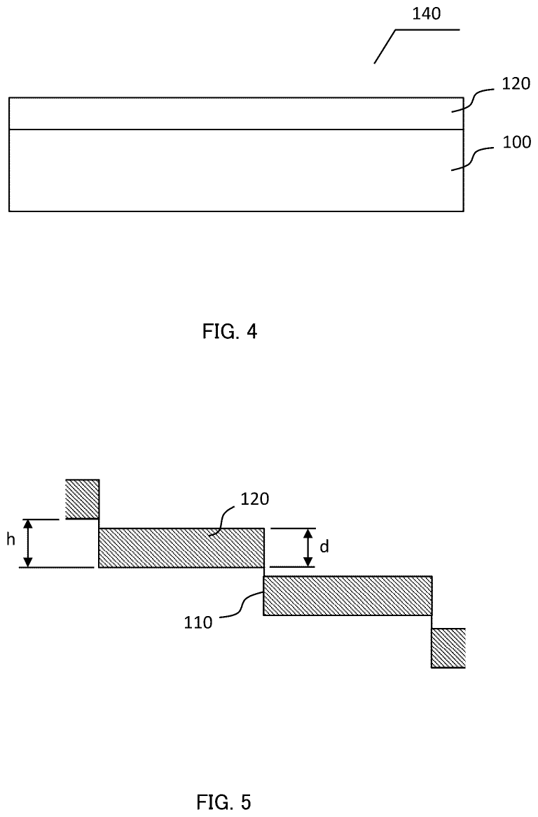

After the terrace portion 102 and the step portion 110 have been formed on the first surface 101 of the first substrate 100, a first semiconductor layer 120 is formed such that a part of the step portion 110 is exposed (S12). FIG. 4 shows an example in which the first semiconductor layer 120 is formed on the surface of the first substrate 100 according to the present embodiment, on which the terrace portion 102 and the step portion 110 are formed. In addition, FIG. 5 is a schematic diagram of a substrate cross section obtained by enlarging a cross section of the surface of the first substrate 100 on which the first semiconductor layer 120 of FIG. 4 is formed. It should be noted that a substrate in which the first semiconductor layer 120 is formed on the first substrate 100 is referred to as a seed layer growth substrate 140.

The first semiconductor layer 120 is grown by MOCVD, for example. In order to prevent misfit dislocation generation and form a high-quality semiconductor layer (semiconductor single crystal layer), it is desirable to select, as the first semiconductor layer 120, a semiconductor material with a lattice constant having a small difference from a lattice constant of the first substrate 100. For example, the difference between the lattice constant of the first substrate 100 and the lattice constant of the first semiconductor layer 120 may be 4% or less. Two percent or less is more desirable for the difference between the lattice constants.

In a case where the first substrate 100 is an SiC single crystal substrate, aluminum nitride (AlN) is a preferable example for the first semiconductor layer 120. The difference in the lattice constants (lattice mismatch ratio) between SiC and AlN is as small as 1.27%, and thus it is possible to prevent misfit dislocation generation as much as possible. In this embodiment, an example in which AlN is used as an example of the first semiconductor layer 120 will be described.

A thickness d of the first semiconductor layer 120 is desirably set to be equal to or less than the step height h of the first substrate 100. More preferably, the thickness d of the first semiconductor layer 120 is set to be smaller than the step height h as shown in FIG. 5. Setting the thickness d of the first semiconductor layer 120 to be smaller than the step height h makes it possible to expose a part of the step portion 110 after the first semiconductor layer 120 has been formed.

For example, the first semiconductor layer 120 is formed by depositing a material of the first semiconductor layer 120 having a thickness that is equal to or less than the height h of the step portion 110, on the surface of the first substrate 100 on which the terrace portion 102 and the step portion 110 are formed. In this case, a nucleus of the semiconductor material is formed on an end portion or a plane of the terrace portion 102, growth proceeds two-dimensionally or three-dimensionally, and crystal growth proceeds such that the entire surface of the terrace portion 102 is covered with the semiconductor material.

Here, a misfit dislocation due to a lattice mismatch may be formed in parallel to the growth interface. However, since the mismatch between the lattice constants of SiC and AlN is small, stress applied to an AlN crystal growth layer is small, and thus it is possible to prevent dislocations penetrating the upper surface of the crystal growth layer formed during the growth of the semiconductor material of the first semiconductor layer 120. As a result, it is possible to form a good first semiconductor layer 120 with few defects.

In practice, the step height h and the thickness d of the first semiconductor layer 120 may vary within a plane of the first substrate 100. Accordingly, it is possible to determine the growth condition of the first semiconductor layer 120 so that the thickness d of the first semiconductor layer 120 becomes equal to or less than the step height h, in consideration of such variations.

Even if the lattice constant mismatch ratio is several percent, most of dislocations associated with a lattice mismatch at the growth temperature of the first semiconductor layer 120 are misfit dislocations that are present at the interface between the first substrate 100 and the first semiconductor layer 120. Such dislocations are not threading dislocations that degrade the crystallinity of a growth layer such that a crystal defect reaches the upper portion of the first semiconductor layer 120. Therefore, even though the thickness of the first semiconductor layer 120 is grown to be equal to or greater than a critical film thickness, the c-axis orientation and the a-axis orientation are appropriately controlled, and thus it is possible to form the first semiconductor layer 120 as an extremely-low dislocation density single crystal with dislocation density of 10² cm⁻² or less.

Here, the step height h of the first semiconductor layer 120 can be designed on the basis of the growth condition of the first semiconductor layer 120 to be formed on the first substrate 100. In a case of forming the first semiconductor layer 120 by MOCVD, which is suitable for practical production, the height of the step portion 110 is set to be equal to or larger than the critical film thickness of the first semiconductor layer 120 obtained by growing crystals on the first substrate 100, in consideration of conditions or the like of the growth rate of the semiconductor layer by MOCVD, for example.

Here, in a case of growing AlN having a small lattice constant difference from SiC on the SiC single crystal substrate, the critical film thickness is about 3 nm. Accordingly, the height h of the step portion 110 is set within the range of 5 nm or more and 200 nm or less, which includes values that are greater than about 3 nm. More preferably, the height h of the step portion 110 may be within the range of 30 nm to 100 nm, which facilitates growth control of the first semiconductor layer 120.

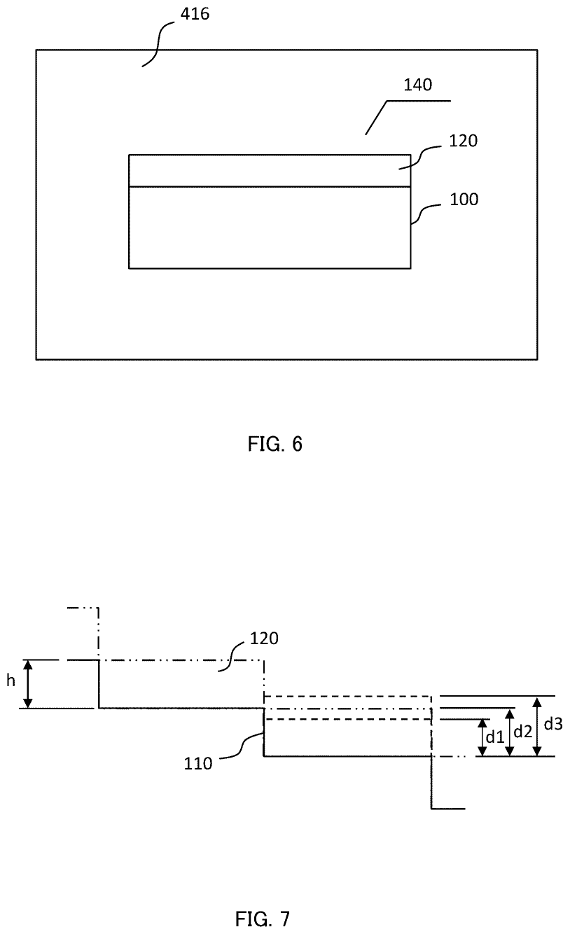

Next, a buffer layer 130 is formed by performing heat treatment on the first substrate 100 on which the first semiconductor layer 120 is formed (S13). FIG. 6 shows an example in which high-temperature heat treatment is performed on the seed layer growth substrate 140 according to the present embodiment in a high-temperature heating furnace 416. The high-temperature heating furnace 416 performs high-temperature heat treatment on the seed layer growth substrate 140 in an inert gas atmosphere such as nitrogen (N₂) gas or argon (Ar) gas. The high-temperature heating furnace 416 may be a furnace that is different from a furnace for growing the first semiconductor layer 120, or may be a furnace for growing the first semiconductor layer 120 as long as it is provided with a heating apparatus capable of raising the in-furnace temperature to a predetermined high-temperature range.

The temperature of high-temperature heat treatment may be higher than the temperature at which the first semiconductor layer 120 is grown. For example, if the first semiconductor layer 120 is AlN, the growth temperature of AlN can be set to 1000° C. to 1200° C., so that the temperature of high-temperature heat treatment can be set in the range between 1300° C. and 2000° C.

Such high-temperature heat treatment thermally decomposes SiC on the surface of the SiC single crystal substrate to desorb Si. For example, in a case where an SiC single crystal substrate is used as the first substrate 100, Si vaporizes from the step portion 110 exposed from the first semiconductor layer 120 on the surface of the first substrate 100, and C, after Si has been desorbed by thermal decomposition of SiC, remains between the first semiconductor layer 120 and the surface of the first substrate 100. C atoms remaining between the first semiconductor layer 120 and the surface of the first substrate 100 forms a two-dimensional bond with each other to form at least one graphene layer, for example several graphene layers.

As described above, high-temperature heat treatment vaporizes a portion of Si of the first substrate 100 from a part of the step portion 110 exposed from the first semiconductor layer 120, to form the buffer layer 130 having at least one graphene layer in at least a part between the first semiconductor layer 120 and the first substrate 100. In other words, exposing a part of the step portion 110 from the first semiconductor layer 120 makes it possible to efficiently vaporize an element of the first substrate 100 that has been thermally decomposed from the exposed step portion 110. It should be noted that the element that vaporizes due to thermal decomposition is Si if the first substrate 100 is an SiC single crystal substrate.

It should be noted that, in the above-described high-temperature heat treatment, since the heating temperature is higher than the temperature at which the first semiconductor layer 120 is grown, the surface of the first semiconductor layer 120 is also thermally decomposed during the high-temperature heat treatment process, which may reduce the thickness of the first semiconductor layer 120. FIG. 7 shows an example in which the first semiconductor layer 120 is grown by changing its thickness with respect to the height h of the step portion 110 according to the present embodiment. FIG. 7 shows three examples of a case where the thickness of the first semiconductor layer 120 is small (the thickness of the first semiconductor layer 120=d1<h); a case where the thickness of the first semiconductor layer 120 is equal (the thickness of the first semiconductor layer 120=d2=h); and a case where the thickness of the first semiconductor layer 120 is large (the thickness of the first semiconductor layer 120=d3>h), with respect to the height h of the step portion 110.

If the thickness of the first semiconductor layer 120 is small with respect to the step height h (h>d1) in a plane of the first substrate 100, a graphene layer can be formed between the first substrate 100 and the first semiconductor layer 120 by high-temperature heat treatment as described above. Further, if the thickness of the first semiconductor layer 120 is equal with respect to the step height h (h=d2), a graphene layer can be formed between the first substrate 100 and the first semiconductor layer 120 by vaporizing Si while vaporizing the surface of the first semiconductor layer 120.

On the other hand, if the thickness of the first semiconductor layer 120 is large with respect to the step height h (h<d3), since the step portion 110 is covered with the first semiconductor layer 120, Si does not vaporize from the step portion 110 at the initial stage of the high-temperature heat treatment process, and thus a graphene layer is not formed. However, since the thickness of the first semiconductor layer 120 is reduced by high-temperature heat treatment, Si can be vaporized from the exposed step portion 110 by performing high-temperature heat treatment so as to expose the step portion 110 and continuing the high-temperature heat treatment further.

Therefore, even though there is a region of the first semiconductor layer 120 where h<d3 in a plane of the first substrate 100 before high-temperature heat treatment, the graphene layer can be formed between the first substrate 100 and the first semiconductor layer 120 by setting conditions of high-temperature heat treatment. In other words, in S12, the first semiconductor layer 120 may be formed such that it covers the step portion 110, on the surface of the first substrate 100 on which the terrace portion 102 and the step portion 110 are formed. In this case, in S13, the graphene layer can be formed by performing high-temperature heat treatment so as to expose a part of the step portion 110 and continuing the high-temperature heat treatment further.

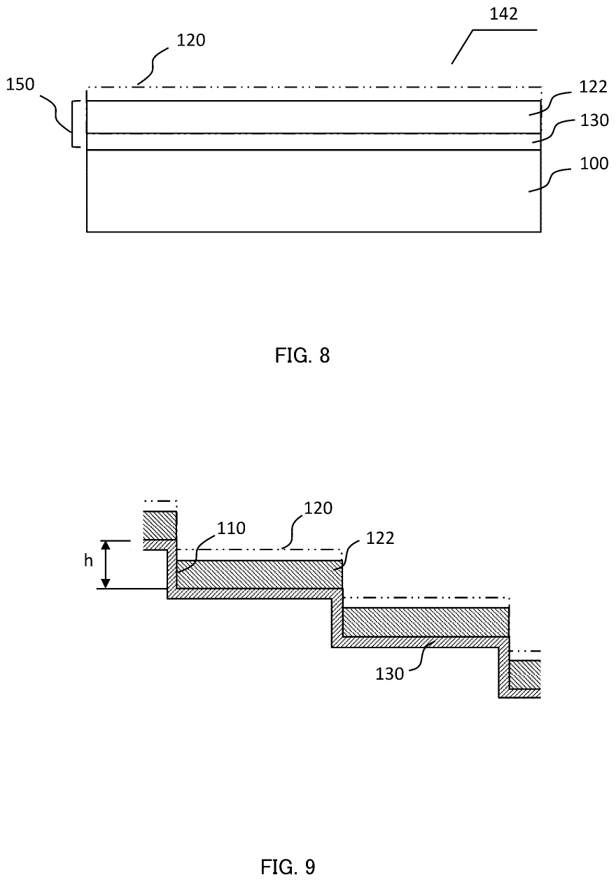

FIG. 8 is a diagram schematically showing the state after high-temperature heat treatment has been performed on the seed layer growth substrate 140 according to the present embodiment. It should be noted that the seed layer growth substrate 140 after high-temperature heat treatment may be referred to as a substrate for crystal growth 142. The thickness of the first semiconductor layer 120 could be reduced by being heated at a temperature that is higher than the growth temperature of this first semiconductor layer 120.

In the present embodiment, the first semiconductor layer 120 with a reduced layer thickness may be referred to as a residual seed layer 122. In other words, the residual seed layer 122 indicates the first semiconductor layer 120 formed on the first substrate 100. Further, at the interface between the first substrate 100 and the first semiconductor layer 120, the bonding of constituent atoms of the substrate is broken on the surface of the first substrate 100 to vaporize a portion of the constituent atoms, thereby forming the buffer layer 130.

For example, if the first substrate 100 is an SiC single crystal substrate and the first semiconductor layer 120 is AlN, an AlN first semiconductor layer 120 is reduced in thickness by the above-described high-temperature heat treatment to become an AlN residual seed layer 122. At the interface between the AlN first semiconductor layer 120 and the first substrate 100, which is the SiC single crystal substrate, SiC is thermally decomposed to vaporize Si, thereby forming the buffer layer 130 (a graphene layer) having graphene in which C atoms are two-dimensionally bonded to each other. Here, the thickness of the buffer layer 130 is the thickness of one layer of graphene (0.67 nm) or a plurality of layers of graphene (0.67 nm×n where n is an integer).

FIG. 9 is a diagram schematically showing the state of the surface of the seed layer growth substrate 140 after the high-temperature heat treatment shown in FIG. 8. In FIG. 9, the first semiconductor layer 120 that is thinner than the step height h is reduced in thickness by high-temperature heat treatment to become the residual seed layer 122.

Further, the buffer layer 130 is formed at the interface between the first substrate 100 and the first semiconductor layer 120. The buffer layer 130 may be epitaxial graphene or turbostratic graphene, for example. In the present embodiment, the residual seed layer 122 and the buffer layer 130 formed by high-temperature heat treatment may be referred to as an intermediate layer 150 for growing a high-quality semiconductor layer (semiconductor single crystal layer) on the residual seed layer 122.

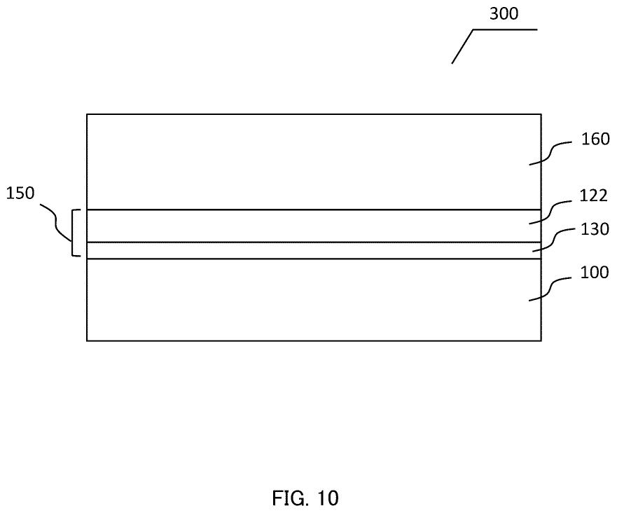

Next, a second semiconductor layer 160 is formed on the upper surface of the first semiconductor layer 120 (S14). FIG. 10 shows an example in which the second semiconductor layer 160 is crystal-grown on the upper surface of the intermediate layer 150 according to the present embodiment. The second semiconductor layer 160 is desirably a single crystal semiconductor layer.

It is desirable to use metal-organic chemical vapor deposition (MOCVD), a sputtering method, or the like for the crystal growth of the second semiconductor layer 160 in view of increasing the size of a wafer and efficient production. If the residual seed layer 122 is AlN, the material of the second semiconductor layer 160 includes at least one of a single-element semiconductor material, a group III-V nitride semiconductor material, or a group II-VI compound semiconductor material. The second semiconductor layer 160 includes at least one of Si, AlₓGa₁₋ₓN, InₓGa₁₋ₓN, or AlₓGa_{y}In_{1-x-y}N (0≤x, y≤1), for example. As far as the thickness of the second semiconductor layer 160 is equal to or greater than the thickness of a basic lattice of a crystal of the material, the second semiconductor layer 160 can be grown to have a thickness depending on the purpose.

In the crystal growth of the second semiconductor layer 160, it is desirable to grow crystals with extremely-low dislocation density by controlling orientations in the c-axis direction and the a-axis direction. Here, the extremely-low dislocation density refers to dislocation density of 10² cm⁻² or less by an evaluation method such as potassium hydroxide (KOH) etching and a transmission electron microscope.

If the residual seed layer 122 is AlN (if the first substrate 100 is SiC and the intermediate layer 150 is an AlN layer/graphene layer), Si is preferable as a single-element semiconductor for the second semiconductor layer 160. As a group III-V compound semiconductor, the second semiconductor layer 160 is preferably formed of a hexagonal compound semiconductor, such as a group III-V nitride semiconductor including GaN, InN and AlGaN mixed crystal, InGaN mixed crystal, InAlN mixed crystal, or the like, for example.

Si can have an atomic arrangement that approximately lattice-matches the c-plane of the hexagonal crystal, and can control orientations in the c-axis direction and the a-axis direction. It should be noted that a difference in lattice constants and/or a difference in thermal expansion coefficients may occur between the second semiconductor layer 160 and the residual seed layer 122, even with such a second semiconductor layer 160. Such a difference in lattice constants and/or a difference in thermal expansion coefficients may generate stress to cause crystal strain.

However, the thickness of the residual seed layer 122 is thinner than the height h of the step portion 110 on the surface of the first substrate 100, and is about 100 nm at most, for example. Therefore, even if a difference in lattice constants and/or a difference in thermal expansion coefficients occurs between the second semiconductor layer 160 and the residual seed layer 122, the buffer layer 130 or the intermediate layer 150 absorbs crystal strain caused by stress, making it possible to prevent dislocation generation in the second semiconductor layer 160.

As a result, it is possible to crystal-grow the second semiconductor layer 160 with extremely-low dislocation density. In other words, it is possible to manufacture the first semiconductor substrate 300 having the second semiconductor layer 160 with extremely-low dislocation density. Such a second semiconductor layer 160 of the first semiconductor substrate 300 can be used as a semiconductor layer for manufacturing a predetermined device.

It should be noted that the second semiconductor layer 160 may be crystal-grown after a part of the residual seed layer 122 on the first substrate 100 has been vaporized or removed. In this case, a region where the buffer layer 130 and the second semiconductor layer are in contact with each other, or a region where the first substrate 100 and the second semiconductor layer 160 are in contact with each other may be formed in a region where a part of the residual seed layer 122 has been vaporized or removed.

As described above, according to the flow of manufacturing a semiconductor substrate according to the present embodiment, it is possible to form a high-quality second semiconductor layer 160 with dislocation density of less than 10⁴ cm⁻² on the first substrate 100 in an area exceeding 1 cm². It should be noted that, although it is possible to provide the manufactured first semiconductor substrate 300, it is also possible to provide the seed layer growth substrate 140 as a substrate for manufacturing a high-quality second semiconductor layer 160.

Further, it is also possible to provide a substrate in which a predetermined device is formed after a predetermined device has been further formed in the second semiconductor layer 160 and on the second semiconductor layer 160. A street line that separates predetermined device regions may be formed on the substrate on which the predetermined device is formed. In the region of the street line, the second semiconductor layer 160 and the intermediate layer 150 may be removed to expose the surface of the first substrate 100.

### <Verification Experiment 1>

The inventor verified that a high-quality second semiconductor layer 160 with extremely-low dislocation density can be obtained, by actually performing the flow of manufacturing a semiconductor substrate according to the present embodiment described above. An SiC single crystal substrate was prepared as the first substrate 100. The size of the first substrate 100 was 10 mm×10 mm×350 μm. The off-angle of the first surface 101 of the first substrate 100 was 4° in the (11-20) direction.

Next, the terrace portion 102 and the step portion 110 were formed by hydrogen etching to control the step height h of the surface of the first substrate 100 to be 50 nm to 60 nm. Then, single crystal AlN was crystal-grown as the first semiconductor layer 120 in a single domain on the surface of the first substrate 100. The thickness of the first semiconductor layer 120 was set to 40 nm. Here, the thickness of the first semiconductor layer 120 may be equal to or greater than the critical thickness.

Next, heat treatment was performed in a nitrogen atmosphere at 1650° C. at 500 Torr for 20 minutes using a high-temperature heat treatment apparatus. It was confirmed that an AlN layer/graphene layer was formed on the first substrate 100 by this high-temperature heat treatment. Here, the AlN layer corresponds to the residual seed layer 122, and the graphene layer corresponds to the buffer layer 130. That is, the intermediate layer 150 (AlN layer/graphene layer) was formed on the SiC single crystal substrate.

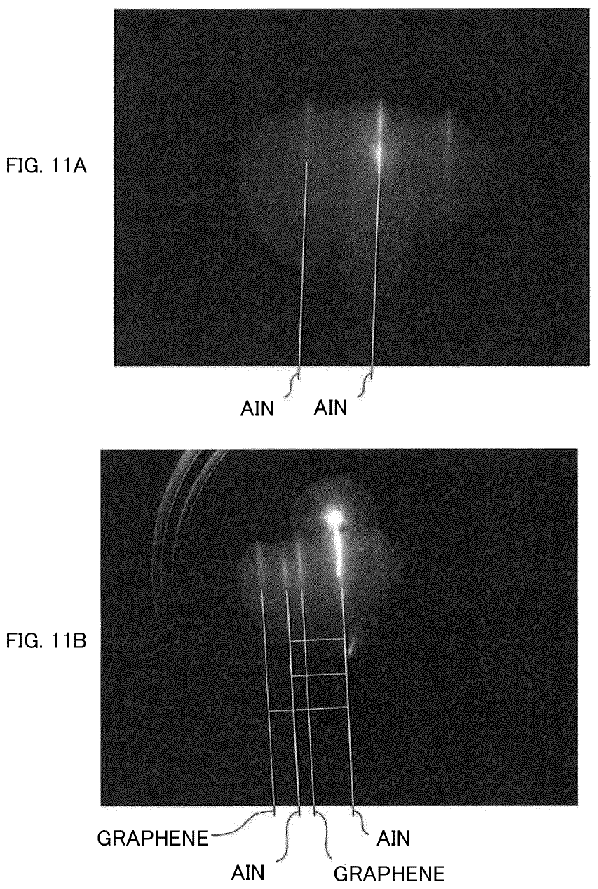

FIGS. 11A and 11B show a first example of reflection high-energy electron diffraction (RHEED) images of the first semiconductor layer 120 formed in this manner. FIG. 11A shows an example of a reflection high-energy electron diffraction image of the first semiconductor layer 120 before high-temperature heat treatment. Further, FIG. 11B shows an example of a reflection high-energy electron diffraction image of the surface of the intermediate layer 150 after high-temperature heat treatment.

Is should be noted that FIGS. 11A and 11B are diffraction images in a case where the direction of electrons was set to be parallel to [10-10]. In the reflection high-energy electron diffraction image of FIG. 11A, streaks with an interval corresponding to the lattice constant of AlN were observed as shown in the figure. From this result, it was confirmed that a single crystal AlN layer was formed as the first semiconductor layer 120 on the SiC single crystal substrate.

In the reflection high-energy electron diffraction image of FIG. 11B, streaks with intervals corresponding to the lattice constants of AlN and graphene were observed as shown in the figure. From this result, it was confirmed that the single crystal AlN layer remained as the residual seed layer 122 on the SiC single crystal substrate, and that the graphene layer serving as the buffer layer 130 was formed.

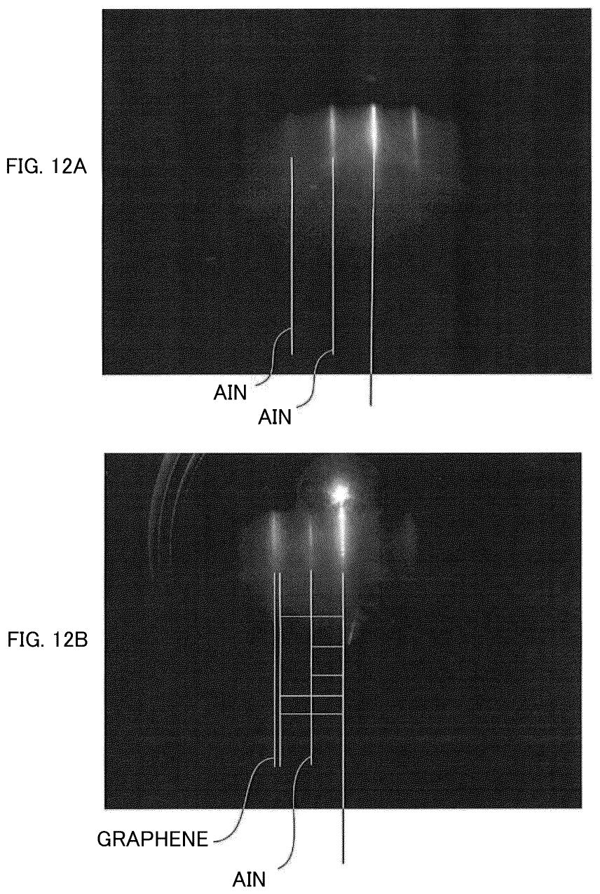

FIGS. 12A and 12B show a second example of reflection high-energy electron diffraction images of the formed first semiconductor layer 120. FIG. 12A shows a second example of a reflection high-energy electron diffraction image of the first semiconductor layer 120 before high-temperature heat treatment, and FIG. 12B shows a second example of a reflection high-energy electron diffraction image of the surface of the intermediate layer 150 formed after high-temperature heat treatment. It should be noted that FIGS. 12A and 12B are diffraction images in a case where the direction of electrons was set to be parallel to [11-20].

In the reflection high-energy electron diffraction image of FIG. 12A, streaks with intervals corresponding to the lattice constant of AlN were observed as shown in the figure. From this result, it was confirmed that a single crystal AlN layer was formed as the first semiconductor layer 120 on the SiC single crystal substrate. In the reflection high-energy electron diffraction image of FIG. 12B, streaks with intervals corresponding to the lattice constants of AlN and graphene were observed as shown in the figure. From this result, it was confirmed that the single crystal AlN layer remained as the residual seed layer 122 on the SiC single crystal substrate, and that the graphene layer was formed as the buffer layer 130.

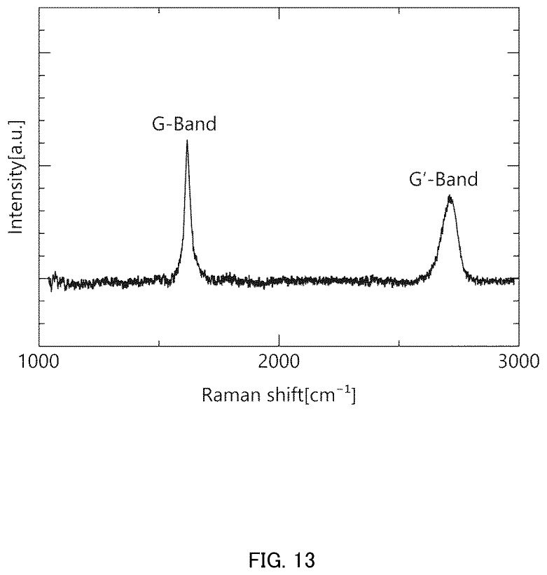

FIG. 13 shows an example of a Raman scattering spectrum of the surface of the intermediate layer 150 formed by high-temperature heat treatment. As shown in FIG. 13, a G band was observed at the left peak in the figure, and a G′ band was observed at the right peak in the figure, from the Raman scattering spectrum. From the intensity ratio of the G band and the G′ band, it was confirmed that the buffer layer 130 composed of two atomic layers of graphene was formed between the first substrate 100 and the residual seed layer 122.

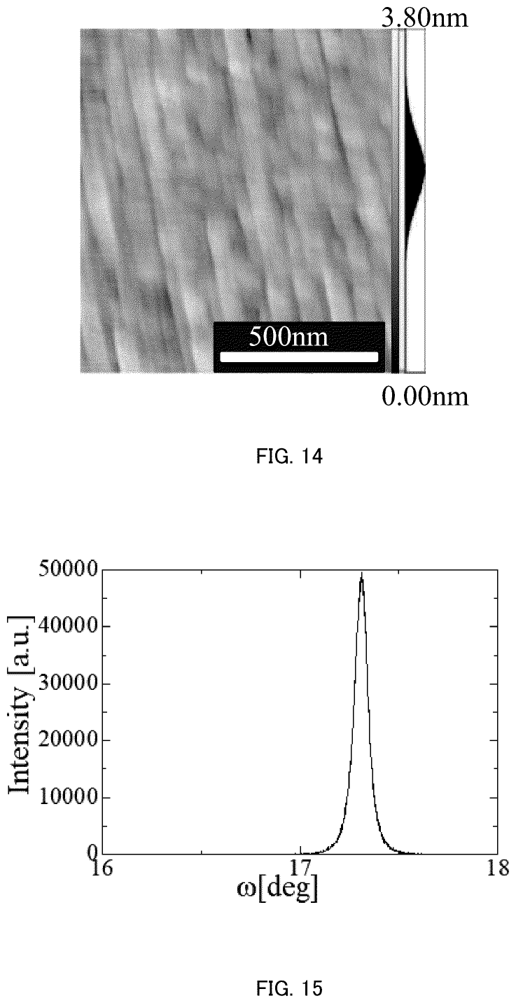

FIG. 14 shows an example of a surface image obtained by observing the surface of the formed intermediate layer 150 with an atomic force microscope (AFM). FIG. 14 shows a result of observing the surface of the intermediate layer 150 formed after high-temperature heat treatment. The scanning area of the atomic force microscope is 1000 nm×1000 nm.

As shown in FIG. 14, it was confirmed that the height difference (a peak-to-valley value) of the surface image according to atomic force microscopy was 3.8 nm. In other words, it was confirmed that the surface of the residual seed layer 122, which becomes the surface of the intermediate layer 150 was flat at the atomic level. In addition, it was confirmed that no abnormality indicating the presence of dislocations or domains was observed in the AFM image.

A GaN layer serving as the second semiconductor layer 160 was grown, by MOCVD, on the upper surface of the intermediate layer 150, which was manufactured as described above. The thickness of the GaN layer is 1.0 μm. FIG. 15 shows an example of a symmetric reflection X-ray rocking curve of the second semiconductor layer 160 formed in this manner. FIG. 15 is a symmetric reflection X-ray rocking curve with respect to a [0002] plane of the second semiconductor layer 160.

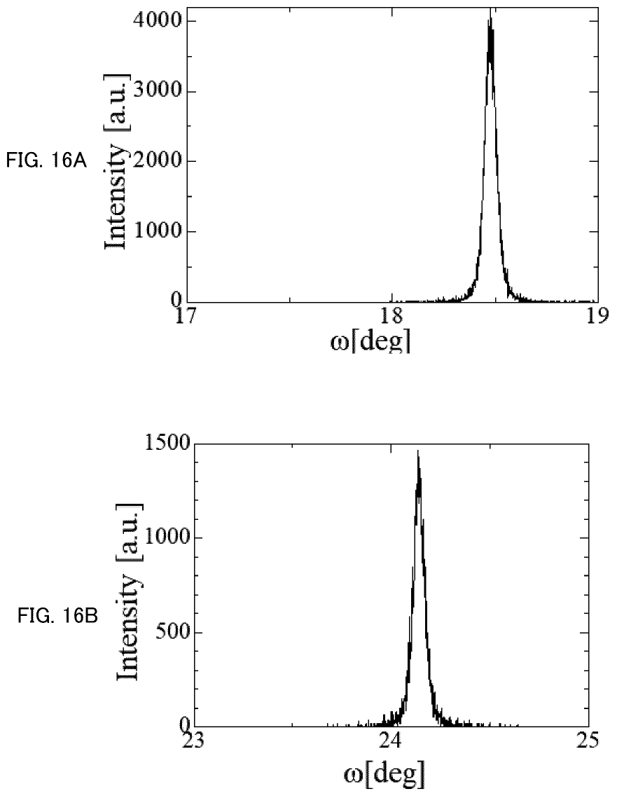

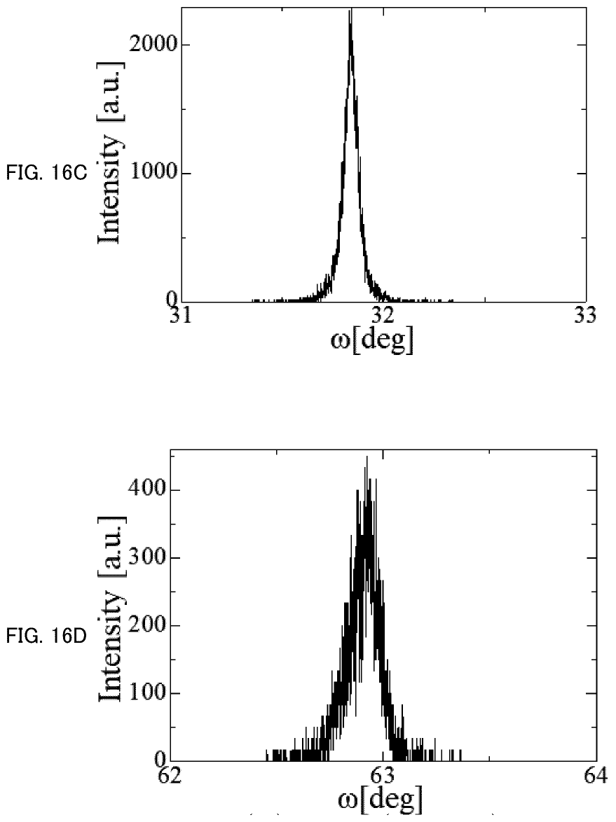

Further, FIGS. 16A to 16D show an example of an asymmetric reflection X-ray rocking curve from the formed second semiconductor layer 160 to other planes. FIGS. 16A to 16D are asymmetrical reflection X-ray rocking curves with respect to a [10-11] plane, a [10-12] plane, a [10-13] plane, and a [30-32] plane, respectively.

Although the formed second semiconductor layer 160 is a thin GaN layer of 1 μm, which is susceptible to the influence of an underlying layer, the symmetric reflection X-ray rocking curve shown in FIG. 15 and the asymmetric reflection X-ray rocking curves shown in FIGS. 16A to 16D were obtained, and a small FWHM value of 350 arcsec (350/3600=0.0972[deg]) was obtained as a full width at half maximum (FWHM value) in any rocking curve shown in FIG. 15 and FIGS. 16A to 16D. It should be noted that the higher the crystal quality of a sample is, the smaller the FWHM value of the rocking curve becomes.

The FWHM value=350 arcsec of the symmetric reflection X-ray rocking curve and the asymmetric reflection X-ray rocking curve obtained in the verification experiment is smaller than FWHM values of rocking curves of GaN single crystal growth films known so far. Therefore, it can be said that a second semiconductor layer 160 of higher quality than before can be formed.

In addition, in the conventional art, it has been difficult to obtain a small FWHM value in both a symmetric reflection X-ray rocking curve and an asymmetric reflection X-ray rocking curve. In contrast, since the formed second semiconductor layer 160 can obtain a small FWHM value in both the symmetric reflection X-ray rocking curve and the asymmetric reflection X-ray rocking curve, it was verified that the crystal quality of the second semiconductor layer 160 can be significantly improved as compared with the conventional art.

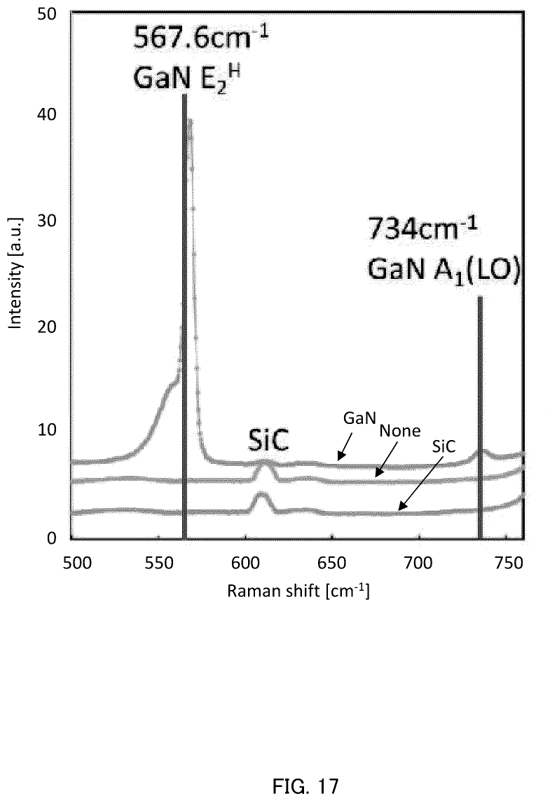

FIG. 17 shows a Raman scattering spectrum of the formed second semiconductor layer 160. As shown in FIG. 17, from the peak of the GaN-LO phonon mode in the Raman scattering spectrum, it can be seen that interfacial stress hardly acts on the second semiconductor layer 160 that has been crystal-grown.

Further, a sample in which the same AlN layer as the residual seed layer 122 in the above verification experiment was grown to have a thickness of 1.0 m on the surface of the intermediate layer 150 was prepared, and a Raman scattering spectrum of the prepared sample was measured in the same manner. As a result, no peak shift of AlN due to interfacial stress was observed in the Raman scattering spectrum. Therefore, it can be seen that there is little interfacial stress acting on the residual seed layer 122 as well.

### <Verification Experiment 2>

In addition to the above-described verification experiment 1, a verification experiment 2 in which the step height h was set to ⅓ was performed. In the verification experiment 2, an SiC single crystal substrate was prepared as the first substrate 100, and surface treatment was performed so as to form a step having a step height h of 20 nm by performing etching. Then, two samples in which a single crystal AlN layer having a respective layer thickness of 5 nm and 10 nm was formed as the first semiconductor layer 120 on the surface of the first substrate 100 were prepared. In both of the two samples, the thickness of the first semiconductor layer 120 was set to a value that is smaller than the step height h of the first substrate 100.

After the first semiconductor layer 120 was formed, high-temperature heat treatment (in a nitrogen atmosphere at 1650° C., which is the same condition as in the verification experiment 1) was performed. Then, in a similar manner as described in the verification experiment 1, it was confirmed that a laminated structure of a residual AlN layer/graphene layer was formed, as the intermediate layer 150, on the upper surface of the first semiconductor layer 120 by high-temperature heat treatment.

Next, a GaN layer having a thickness of 560 nm was formed as the second semiconductor layer 160 on the upper surface of the intermediate layer 150 by MOCVD. Then, the crystal quality of the second semiconductor layer 160 of the manufactured sample was evaluated by the same method as in the verification experiment 1.

In a similar manner as in the verification experiment 1, FWHM values of symmetric reflection and asymmetric reflection X-ray rocking curves are each a small value of 350 arcsec or less, and it was verified that it was possible to form a high-quality second semiconductor layer 160 even though the step portion 110 having the step height h of the first substrate 100 was formed by controlling the step height h within a relatively small range. Further, in a similar manner as in the verification experiment 1, it was also confirmed that no peak shift due to interfacial stress was observed in the Raman scattering spectrum of the second semiconductor layer 160.

The results of the verification experiment 1 and the verification experiment 2 demonstrate that it is possible to form a second semiconductor layer 160 of higher quality than those of the conventional art on the upper surface of the first substrate 100. Further, the results of the above-described verification experiments show that it is possible to form the second semiconductor layer 160, as a high-quality single crystal semiconductor layer with extremely-low dislocation density (dislocation density of 10² cm⁻² or less) in which the crystal orientation is controlled, on the upper surface of the first substrate 100, even in consideration of the fluctuation in i) the plane orientation of the SiC single crystal substrate after the crystal growth of the second semiconductor layer 160 and ii) the crystal axis of the second semiconductor layer 160 dependent on the film thickness of the second semiconductor layer 160.

According to the flow of manufacturing a semiconductor substrate of the present embodiment, it is possible to form the buffer layer 130 between the first substrate 100 and the first semiconductor layer 120 by forming the first semiconductor layer 120 covering the upper surface of the first substrate 100 on the first substrate 100, and then performing high-temperature heat treatment. Here, exposing an end portion of the step portion 110 formed on the first substrate 100 from the first semiconductor layer 120 makes it possible to efficiently vaporize (sublimate) a portion of material atoms forming the first substrate 100 from the end portion of the step portion 110. This makes it possible to form a uniform buffer layer 130 having no covalent bonding to the surface of the first substrate 100, on the entire surface of the first substrate 100.

In addition, the intermediate layer 150 has a laminated structure of such a buffer layer 130 and the thin-film residual seed layer 122, and is a layer for crystal-growing the second semiconductor layer 160 on its upper surface. Even though there is a difference in lattice constants and/or a difference in thermal expansion coefficients between the first substrate 100 and the second semiconductor layer 160, such an intermediate layer 150 allows the buffer layer 130 to mitigate the difference in the lattice constants and the difference in the thermal expansion coefficients.

Therefore, it is possible to form a high-quality second semiconductor layer 160 with extremely-low dislocation density over the entire upper surface of the first substrate 100. In other words, it is possible to obtain a high-quality second semiconductor layer 160 with a predetermined composition and extremely-low dislocation density, whose c-axis orientation and a-axis orientation are appropriately controlled, on the upper surface of the first substrate 100.

In addition, a step and the first semiconductor layer 120 to be formed on the surface of the first substrate 100 may be formed such that an end portion of the step portion 110 is exposed from the first semiconductor layer 120. For example, a step having an average height h is formed on the surface of the first substrate 100, and the first semiconductor layer 120 is formed to have a layer thickness that is equal to or less than this average height h. As described above, in the first semiconductor layer 120, it is not necessary to perform precise crystal growth control at the atomic layer level, and it is possible to achieve highly efficient crystal growth by MOCVD, with the high productivity required for practical use. Therefore, it is also possible to increase the diameter of the first substrate 100.

Further, in general, the cause of reducing the crystal quality of the semiconductor layer is interfacial stress generated along with a mismatch of lattice constants and a mismatch of thermal expansion coefficients between the surface on which crystals are grown and the semiconductor layer that is crystal-grown. The flow of manufacturing a semiconductor substrate according to the present embodiment allows the buffer layer 130 to mitigate a mismatch of the lattice constants and a mismatch of the thermal expansion coefficients between i) the second semiconductor layer 160 that is grown on the upper surface of the residual seed layer 122 and ii) this residual seed layer 122, thereby preventing interfacial stress generation. Therefore, the buffer layer 130, instead of a low-temperature buffer layer in a conventional two-step growth method or the like, makes it possible to obtain a second semiconductor layer 160 with higher quality.

As described above, using the high-quality second semiconductor layer 160 formed in the present embodiment makes it possible to form a semiconductor device having significantly improved characteristics and quality as compared with conventional semiconductor devices. In addition, the range of semiconductors that can be applied as the second semiconductor layer 160 are a single-element semiconductor, a group III-V compound semiconductor, a group II-IV compound semiconductor, or the like, and these semiconductors can be widely applied as a material to be formed as a semiconductor device.

In particular, a group III-V nitride semiconductor mixed crystal generally has a high-density edge dislocation and a threading dislocation due to a mismatch of lattice constants and a mismatch of thermal expansion coefficients. The group III-V nitride semiconductor mixed crystal exhibits n-type electrical characteristics having a high residual electron concentration since such dislocations (lattice defects) serve as a donor. Therefore, it has been difficult to control the p-type conductivity of the group III-V nitride semiconductor mixed crystal even though acceptor impurities are added thereto. However, since crystal defects in the second semiconductor layer 160 formed in the present embodiment can be controlled to be low density, it is possible to control the p-type conductivity even though the second semiconductor layer 160 is formed as a group III-V nitride semiconductor mixed crystal.

### <Modification>

In the above embodiment, the single crystal SiC may be doped with an impurity element other than Si and C. Further, although the area of a high-quality semiconductor layer is considered to be limited, the first substrate may be polycrystalline SiC. At this time, an element other than Si and C, such as O may be contained.

In the present embodiment described above, an example in which MOCVD is used as means for crystal-growing the first semiconductor layer 120 has been described, but the present disclosure is not limited to this. A method such as molecular-beam epitaxy (MBE) and laser ablation may be used as means for crystal-growing the first semiconductor layer 120. Even though the first semiconductor layer 120 is crystal-grown by such methods, it is possible to form a high-quality second semiconductor layer 160 on the upper surface of the intermediate layer 150.

Further, in the present embodiment described above, a single crystal substrate formed of a single material is described as an example of the first substrate 100, but the present disclosure is not limited to this. The first substrate 100 may be formed of a composite material. Next, the first substrate 100 formed of such a composite material will be described as a composite material substrate 200.

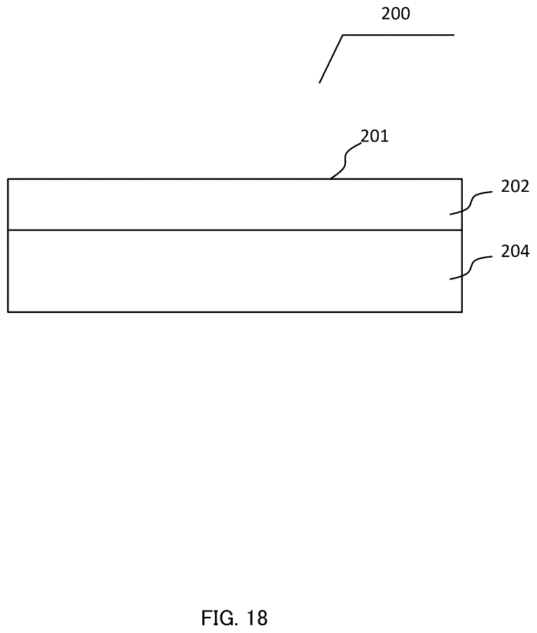

FIG. 18 shows a configuration example of a composite material substrate 200 according to the present embodiment. The composite material substrate 200 includes a first substrate 202 formed of a first material and a second substrate 204 formed of a second material. The first substrate 202 is a single crystal material. The first substrate 202 is an SiC single crystal substrate, for example. In a case where the first substrate 202 is an SiC single crystal substrate, a first surface 201 of the first substrate 202, which is on an opposite side from the second substrate 204, can be an Si surface having an SiC crystal structure, for example. Alternatively, the first surface 201 can be a C surface that is on the opposite side from the Si.

Since the first substrate 202 is reinforced by the second substrate 204, its thickness can be reduced as compared with the first substrate 100 formed of a single material. The thickness of the first substrate 202 can be about 0.5 μm or more, for example. As will be described later, the first substrate 202 desirably has a thickness such that it can be laminated to the upper surface of the second substrate 204, for example.

Further, after the first substrate 202 has been laminated to the second substrate 204, the thickness of the first substrate 202 may be adjusted by polishing the first surface 201 of the first substrate 202, for example. In this case, the thickness of the first substrate 202 can be less than 0.5 μm.

The second substrate 204 can be an SiC sintered substrate. The second material of the second substrate 204 may be another single crystal material or a sintered material such as SiN, AlN, C, or the like.

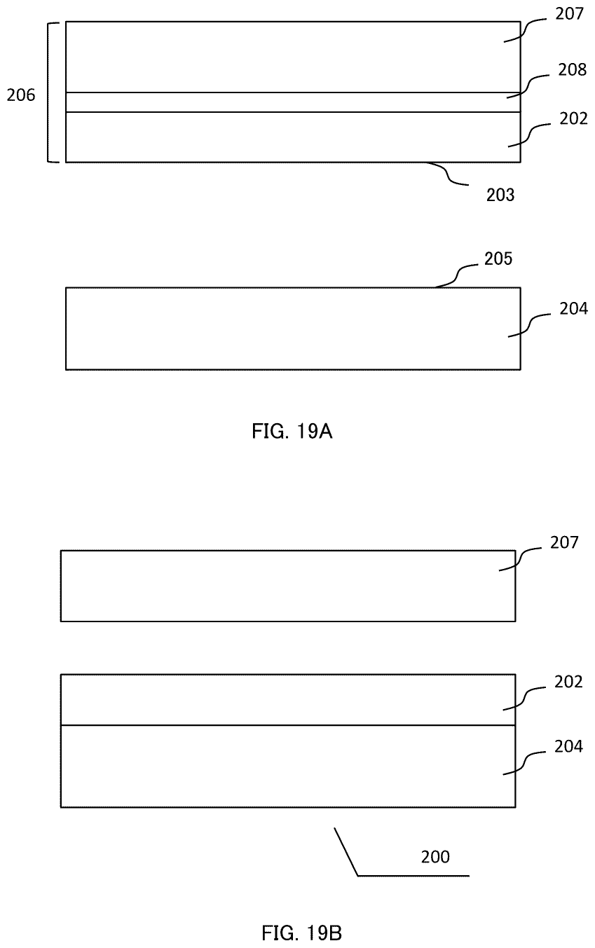

The composite material substrate 200 shown in FIG. 18 can be manufactured as follows, for example. First, a third substrate 206 formed of a first material and a second substrate 204 formed of a second material are prepared. FIGS. 19A and 19B show an example of a composite material substrate composed of the first substrate 202 and the second substrate 204 according to the present embodiment. FIG. 19A shows a configuration example of the third substrate 206 and second substrate 204 that has been prepared. The third substrate 206 and the second substrate 204 have a flat surface such as a second surface 203 and a third surface 205, respectively, that are flat on the nanometer scale, for example.

As shown in FIG. 19A, the third substrate 206 has a separation region 208. The separation region 208 is provided at a position away from the second surface 203 of the third substrate 206 by a predetermined distance. The separation region 208 can be formed as an altered layer formed by implanting ions, such as oxygen ions, for example. Such a separation region 208 allows the third substrate 206 to be mechanically or chemically separated.

Then, when the third substrate 206 is separated by the separation region 208, a part of this third substrate 206 becomes the first substrate 202 and the remaining part becomes a first material substrate portion 207. In other words, the separation region 208 is provided at a position away from the second surface 203 of the third substrate 206 by a predetermined distance, which is set to be the thickness of the first substrate 202 to be separated from the third substrate 206.

Surface treatment such as chemical surface treatment and plasma treatment is performed on the second surface 203 of the third substrate 206 and the third surface 205 of the second substrate 204 as described above, and then these substrates are bonded to each other by being pressed and heated. Bonding can be performed in the air or in a vacuum. Then, after the third substrate 206 and the second substrate 204 have been bonded to each other, they are chemically or mechanically separated by the separation region 208.

FIG. 19B shows an example in which the composite material substrate 200 is formed by bonding the second substrate 204 to the third substrate 206 and then separating them by the separation region 208. Then, the surface of the first substrate 202 bonded to the upper surface of the second substrate 204 is finished to the first surface 201 having a predetermined off-angle, by surface treatment including cleaning or the like and polishing treatment, such as mechanical polishing and chemical polishing. This makes it possible to obtain the composite material substrate 200 in which the first substrate 202 formed of the first material and the second substrate 204 formed of the second material are bonded to each other.

It is possible to form the intermediate layer 150 and the second semiconductor layer 160 on the upper surface of the composite material substrate 200, by executing the operation flow of S10 to S14 shown in FIG. 1 using the above composite material substrate 200 instead of the first substrate 100. Such a composite material substrate 200 can reduce the amount of the first material constituting the substrate, as compared with the first substrate 100 formed of a single material. Therefore, it is possible to use a low-cost material for the second material of the second substrate 204 as compared with the first material, and to reduce costs by reducing the first material, which is a high-quality single crystal material.

### <Formation of the Self-Supporting Semiconductor Substrate>

An example in which the intermediate layer 150 and the second semiconductor layer 160 are formed on the upper surface of the first substrate 100 or the composite material substrate 200 has been described in the flow of manufacturing a semiconductor substrate according to the present embodiment, but the present disclosure is not limited to this. The second semiconductor layer 160 may be formed as a self-supporting semiconductor substrate using the manufacturing flow shown in FIG. 1.

For example, it has been described that it is possible to manufacture the first semiconductor substrate 300 shown in FIG. 10 by growing the second semiconductor layer 160 on the upper surface of the intermediate layer 150 in S14. Here, the thickness of the second semiconductor layer 160 can be grown further to such an extent that a semiconductor manufacturing apparatus can perform operations such as adsorption, transportation, and fixing of only the second semiconductor layer 160. For example, the thickness of the second semiconductor layer 160 can be within the range of 5 m to 1 mm. Here, in view of handling, with the semiconductor manufacturing apparatus, the second semiconductor layer 160 without support by a member such as a supporter, the thickness of the second semiconductor layer 160 may be 1 mm or more.

A method such as MOCVD and HVPE may be used for crystal-growing the second semiconductor layer 160. A plurality of crystal growth methods can also be used in combination. For example, a combination of MOCVD and HVPE can be used. In this case, the second semiconductor layer 160 may be grown to have a certain predetermined thickness by MOCVD, and then further grown to have a predetermined thickness by HVPE, for example.

Also in this case, the intermediate layer 150 can mitigate the influence of stress on the second semiconductor layer 160 due to the difference in the lattice constants and the difference in the thermal expansion coefficients between i) the first substrate 100 and ii) the residual seed layer 122 and the second semiconductor layer 160, and therefore it is possible to crystal-grow a high-quality second semiconductor layer 160 having a predetermined thickness that enables self-support.

After the second semiconductor layer 160 has been grown to have a predetermined thickness, the second semiconductor layer 160 may be separated from the first substrate 100. The second semiconductor layer 160 is connected to the first substrate 100 by the intermediate layer 150, but the buffer layer 130 constituting the intermediate layer 150 has a laminated structure including a single layer or a plurality of layers having two-dimensional bonding.

Each layer of the buffer layer 130 having two-dimensional bonding; the buffer layer 130 and the first surface 101 of the first substrate 100; and the buffer layer 130 and the residual seed layer 122 are each bonded by a weak force such as the van der Waals force. Therefore, it is possible to easily separate the second semiconductor layer 160 from the first substrate 100 as described below, without etching away the buffer layer 130 by a chemical etching method, for example.

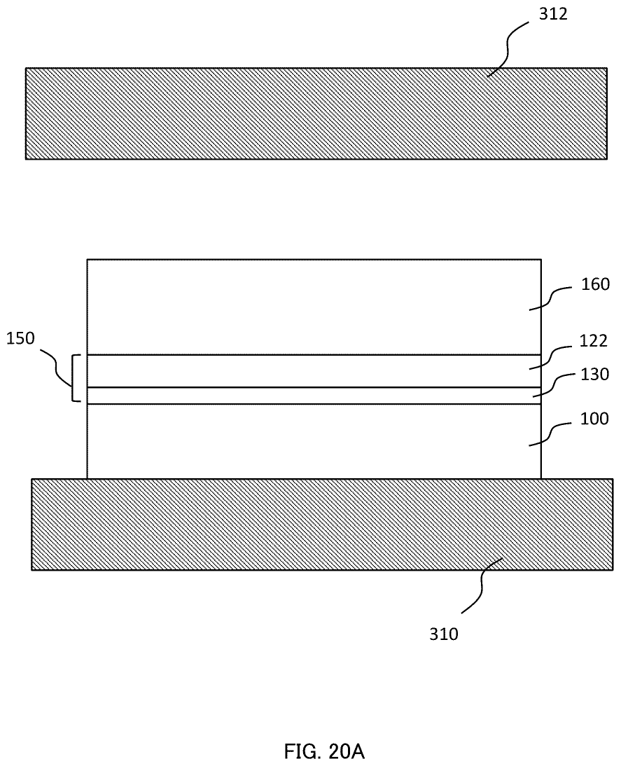

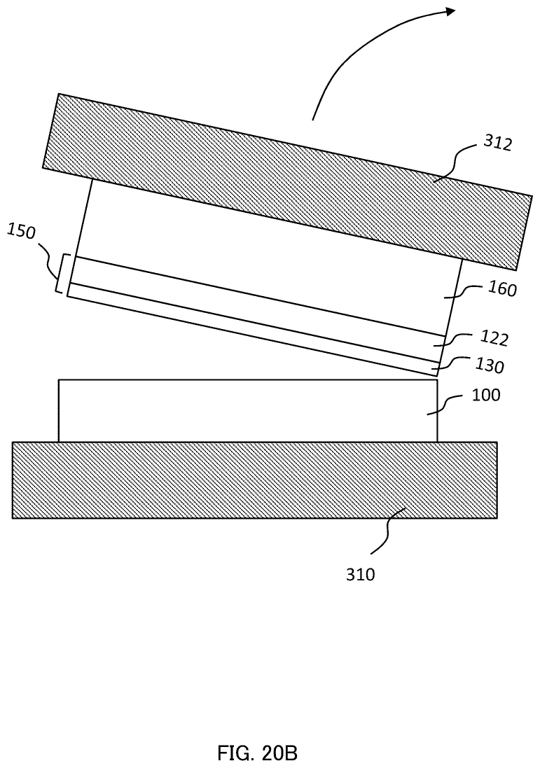

FIG. 20A shows a configuration example in which the second semiconductor layer 160 according to the present embodiment is separated from the first substrate 100. One surface of the first semiconductor substrate 300 obtained by crystal-growing the second semiconductor layer 160 on the first substrate 100 is placed in a separation apparatus having a first fixing stage 310 and a second fixing stage 312. FIG. 20A shows an example in which the bottom surface of the first substrate 100 is fixed by the first fixing stage 310. It should be noted that a configuration of the apparatus of FIGS. 20A and 20B is merely an example, and a method for separating the second semiconductor layer 160 from the first substrate 100 is not limited. A method and apparatus for separation are not limited to the example of FIGS. 20A and 20B, as long as the second semiconductor layer 160 can be mechanically separated from the first substrate 100.

The first fixing stage 310 and the second fixing stage 312 each can be an adsorption stage. In this case, as an adsorption method for the first fixing stage 310 and the second fixing stage 312, it is possible to use vacuum adsorption, electromagnetic adsorption, non-contact adsorption such as a Bernoulli system, a cyclone system, or the like. It is desirable to select an adsorption method suitable for substrate materials to be used, thickness, size, and the like.

Further, as an adsorption method for the first fixing stage 310 and the second fixing stage 312, a substrate to which an adhesive sheet that can be temporarily fixed is attached, a substrate on which adhesive is applied, or the like may be adsorbed by the fixing stage, and the first semiconductor substrate 300 may be fixed via this adhesive sheet or this substrate, for example. It should be noted that the adhesive sheet is an adhesive sheet capable of heat or UV peeling, for example.

Instead of the above adsorption stage, a fixing stage having a heating apparatus for heating the stage or a UV radiation apparatus for radiating UV onto the stage, and an adhesive sheet capable of heat or UV peeling may be used. To fix the first semiconductor substrate 300, the first fixing stage 310 and the second fixing stage 312 may have the same fixing method or may have different fixing methods, and it is desirable that a fixing method can be appropriately changed.

Next, the other side of the first semiconductor substrate 300, for example the surface of the second semiconductor layer 160, is fixed by the second fixing stage 312. Next, in a state where the first semiconductor substrate 300 is fixed to the first fixing stage 310, the second fixing stage 312 is moved to a position where the second semiconductor layer 160 can be separated from the first substrate 100. The second fixing stage 312 desirably includes a mechanism that moves in a direction perpendicular to the surface of the first semiconductor substrate 300, and additionally includes a mechanism that moves in a different direction than a direction perpendicular to the surface of the first semiconductor substrate 300, from the first substrate 100, for example.

FIG. 20B shows a configuration example after the second semiconductor layer 160 according to the present embodiment has been separated from the first substrate 100. As shown in FIG. 20B, it is desirable that a moving mechanism of the second fixing stage 312 is configured such that a trajectory along which the center of the second fixing stage 312 moves forms an arc about the substrate end portion of the first semiconductor substrate 300. It should be noted that FIG. 20B shows an example in which the size of the second fixing stage 312 is larger than the size of the second semiconductor layer 160 to be separated, but the present disclosure is not limited to this. The size of the second fixing stage 312 may be equal to or smaller than the size of the second semiconductor layer 160 to be separated.

Even though the first semiconductor substrate 300 to be moved is a large-diameter wafer and has a large surface area, such a moving mechanism of the second fixing stage 312 makes it possible to separate the second semiconductor layer 160 stably and safely from the first substrate 100 without applying a large load to the entire first semiconductor substrate 300, the first substrate 100, and the second semiconductor layer 160, for example.

It should be noted that, in a case where the size of the second semiconductor layer 160 to be separated is small, for example in a case where its surface area is approximately 100 mm² or less (as an example, in a case where the surface area is equal to or smaller than the size of a square whose length of one side is 10 mm), it is possible to separate the second semiconductor layer 160 easily and safely without causing damage such as a crack to the second semiconductor layer 160, even with a method of moving in the perpendicular direction. In a case of separating a plurality of second semiconductor layers 160, if the size of a region to be separated is small, for example if the area of the target region is approximately 100 mm² or less (as an example, if the area of the target region is equal to or less than the size of a square whose length of one side 10 mm), it is possible to separate the second semiconductor layers 160 easily and safely without causing damage such as a crack to the second semiconductor layers 160, even with a method of moving in the perpendicular direction.

The roles of the first fixing stage 310 and the second fixing stage 312 at the time when the second semiconductor layer 160 is separated from the first substrate 100 can be interchanged. In this case, the first fixing stage 310 may have a moving mechanism and may move the first substrate 100. Further, the first fixing stage 310 and the second fixing stage 312 may have a moving mechanism and may move together.

Next, detaching the second semiconductor layer 160 from the second fixing stage 312 makes it possible to obtain a self-supporting semiconductor substrate including the high-quality second semiconductor layer 160 having the predetermined thickness. The self-supporting semiconductor substrate has a thickness that enables self-support. The self-supporting semiconductor substrate may have a configuration including the second semiconductor layer 160 and the intermediate layer 150, or alternatively, may have a configuration including the second semiconductor layer 160 without including the intermediate layer 150. The intermediate layer 150 can be removed by dry etching using oxygen or chlorine gas, for example. Further, the intermediate layer 150 may be removed by chemical mechanical polishing (CMP).

The first substrate 100 after the second semiconductor layer 160 has been separated therefrom can be reused by removing the buffer layer 130 remaining on the surface of the first substrate 100 on which the intermediate layer 150 is formed. The buffer layer 130 remaining on the surface of the first substrate 100 can be removed by dry etching using oxygen gas, chlorine gas, or the like, for example. When the first substrate 100 is reused, a polishing process such as chemical mechanical polishing (CMP) may be appropriately performed on the surface of the first substrate 100.

As described above, after the second semiconductor layer 160 has been formed on the first substrate 100, a partial region including the formed second semiconductor layer 160 is separated from the first substrate 100, thereby forming a self-supporting semiconductor substrate formed of the second semiconductor layer 160. This makes it possible to obtain a self-supporting semiconductor substrate having significantly higher quality as compared with the conventional art, for a semiconductor substrate such as a group III-V compound semiconductor and group II-VI compound semiconductor having a predetermined mixed crystal ratio of constituent elements, and a semiconductor substrate formed of Si or the like.

In addition, it is possible to obtain a high-quality self-supporting semiconductor substrate having a predetermined thickness without undergoing a processing step such as cutting or polishing of a substrate material or a chemical etching step as undergone in the conventional art. Further, the high-quality self-supporting semiconductor substrate having the predetermined thickness can be separated from the first substrate 100 at the position of the buffer layer 130 without destroying the first substrate 100, so that the first substrate 100 can be reused easily.

In the flow of manufacturing a semiconductor substrate according to the present embodiment, an example in which the second semiconductor layer 160 is separated from the first substrate 100 after the intermediate layer 150 and the second semiconductor layer 160 have been formed on the upper surface of the first substrate 100 or the composite material substrate 200 has been described, but the present disclosure is not limited to this. For example, after the second semiconductor layer 160 has been formed on the first substrate 100 by executing the flow of manufacturing a semiconductor substrate shown in FIG. 1, a reinforcing substrate 350 may be further bonded to the upper surface of the second semiconductor layer 160, and then the second semiconductor layer 160 may be separated from the first substrate 100.

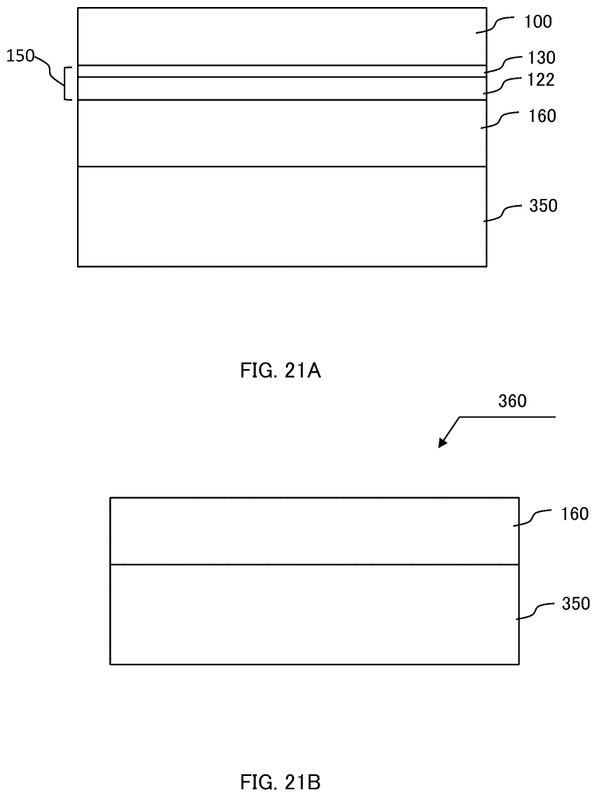

FIG. 21A shows an example in which the reinforcing substrate 350 is bonded to the upper surface of the second semiconductor layer 160 according to the present embodiment. For example, after surface treatment such as cleaning or plasma treatment has been appropriately performed on a surface to be bonded of the second semiconductor layer 160 and a surface to be bonded of the reinforcing substrate 350, their surfaces to be bonded are brought into close contact with each other and pressure is applied, thereby bonding the second semiconductor layer 160 and the reinforcing substrate 350.

A bonding step of bringing their surfaces to be bonded into close contact with each other and applying pressure may be performed in the air or in a vacuum. Such a bonding step may be performed at room temperature or may be performed at an increased temperature. The bonding strength between the second semiconductor layer 160 and the reinforcing substrate 350 is desirably greater than at least the force acting between layers of a two-dimensional layered material constituting the buffer layer 130 (the magnitude of interaction between layers or the bonding force between layers).

After the reinforcing substrate 350 has been bonded to the second semiconductor layer 160, the first substrate 100 and the second semiconductor layer 160 bonded to the reinforcing substrate 350 are separated from each other. For example, in a similar manner as in the method described with reference to FIGS. 20A and 20B, the surface of the first substrate 100 and the surface of the reinforcing substrate 350 are fixed by the first fixing stage 310 and the second fixing stage 312, respectively, and the first fixing stage 310 and/or the second fixing stage 312 is moved to separate the first substrate 100 and the second semiconductor layer 160 from each other.

Etching is performed on the surface of the second semiconductor layer 160 that is on the opposite side from the reinforcing substrate 350, after the first substrate 100 and the second semiconductor layer 160 have been separated from each other. This makes it possible to remove the residual seed layer 122 that is present on the surface of the second semiconductor layer 160 that is on the opposite side from the reinforcing substrate 350, or the residual seed layer 122 and a part of the buffer layer 130. It should be noted that the remaining buffer layer 130 may be removed to leave the residual seed layer 122 on the surface of the second semiconductor layer 160.

Through the above steps, itis possible to manufacture the second semiconductor substrate in which the second semiconductor layer 160 is bonded to the reinforcing substrate 350. FIG. 21B shows a first example of the second semiconductor substrate 360 according to the present embodiment. The procedure of manufacturing the second semiconductor substrate 360 described above is merely an example, and the present disclosure is not limited to this.

For example, in a similar manner as in the method described with reference to FIGS. 20A and 20B, after the first substrate 100 and the second semiconductor layer 160 have been separated from each other, the surface of the separated second semiconductor layer 160 on the side where the first substrate 100 was provided may be bonded to the reinforcing substrate 350. In this case, after a supporter capable of supporting the second semiconductor layer 160 has been provided on the surface of the second semiconductor layer 160 that is on the opposite side from the first substrate 100, the second semiconductor layer 160 may be separated from the first substrate 100. The supporter can support the second semiconductor layer 160 after being separated from the first substrate 100, which allows easy handling of the separated second semiconductor layer 160.

After the second semiconductor layer 160 has been separated from the first substrate 100, apart or all of the buffer layer 130 remaining on the residual seed layer 122 is etched away. Then, the reinforcing substrate 350 is pressed onto the surface of the residual seed layer 122 on the opposite side from the second semiconductor layer 160. A pressing step may be performed in the air, or may be performed in a vacuum instead. Then, the supporter supporting the second semiconductor layer 160 is separated or removed from the second semiconductor layer 160.

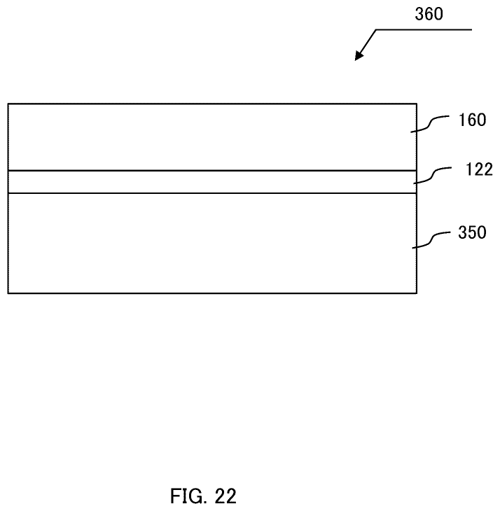

The second semiconductor substrate 360 can be manufactured by the above-described method. FIG. 22 shows a second example of the second semiconductor substrate 360, which has been manufactured as described above, according to the present embodiment. It should be noted that the second semiconductor substrate 360 may be manufactured by forming a predetermined semiconductor device on the second semiconductor layer 160, and then separating the first substrate 100 and bonding the second semiconductor layer 160 to the reinforcing substrate 350.

It should be noted that a device structure such as a circuit element or wiring, and an optical component structure such as an optical waveguide or the like may be formed in a partial region of the reinforcing substrate 350. Further, the reinforcing substrate 350 may include a device, an apparatus, or the like having other functions such as a heat dissipation function in addition to a function of supporting and reinforcing the second semiconductor layer 160.

An embodiment in which the above-described second semiconductor substrate 360 was obtained by bonding the single-layer second semiconductor layer 160 to the upper surface of the reinforcing substrate 350 has been exemplified, but the present disclosure is not limited to this. A region to which the second semiconductor layer 160 is bonded may be the entire surface of the second semiconductor substrate 360 or may be a partial region of the second semiconductor substrate 360.

The second semiconductor substrate 360 may have a structure in which a plurality of second semiconductor layers 160 formed of the same material or different materials are bonded to at least a partial region of the upper surface of the reinforcing substrate 350 by repeating the above-described steps a plurality of times. In this case, the second semiconductor substrate 360 may be formed by stacking a plurality of second semiconductor layers 160 formed of the same material or different materials two-dimensionally or three-dimensionally.

Further, a plurality of second semiconductor layers 160 may be bonded to at least a partial region of the upper surface of the reinforcing substrate 350. In this case, the plurality of second semiconductor layers 160 may be two-dimensionally or three-dimensionally bonded to the reinforcing substrate 350 in an island shape in which the layers are separated from each other. The bonding of the second semiconductor layer of the second semiconductor substrate 360 may be performed with or without the use of adhesive. For example, the bonding may be performed with the use of thermosetting adhesive or UV curing adhesive. The reinforcing substrate 350 may be a semiconductor substrate, a dielectric substrate, a glass substrate, a metal substrate, a resin substrate, or the like.

A circuit element, wiring, or the like may be formed on the reinforcing substrate 350 and/or the second semiconductor substrate 360 before bonding. In this case, the circuit element and wiring of the reinforcing substrate 350 and the second semiconductor substrate 360 may be connected to each other after bonding. Further, after the reinforcing substrate 350 and the second semiconductor substrate 360 have been bonded to each other, the circuit element and wiring may be formed on the second semiconductor substrate 360.

As described above, it is possible to easily manufacture the second semiconductor substrate 360 in which the high-quality second semiconductor layer 160 is separated from the first substrate 100 at the position of the buffer layer 130 and bonded to the upper surface of the reinforcing substrate 350. The second semiconductor substrate 360 can be manufactured without performing etching on the buffer layer 130, and therefore it is possible to bond the high-quality second semiconductor layer 160 to the upper surface of the reinforcing substrate 350 formed of a material that is different from that of the first substrate 100, with a small number of steps. Further, it is possible to reuse the first substrate 100 easily since the second semiconductor layer 160 is separated from the first substrate 100 at the position of the buffer layer 130.

### <The Manufacturing Apparatus>

The above-described first semiconductor substrate 300 and second semiconductor substrate 360 according to the present embodiment can be manufactured using separate and independent semiconductor manufacturing apparatuses, but they can also be manufactured using a dedicated semiconductor manufacturing apparatus, since they can be manufactured with simple manufacturing steps. A manufacturing apparatus for manufacturing the first semiconductor substrate 300 and the second semiconductor substrate 360 will now be described.

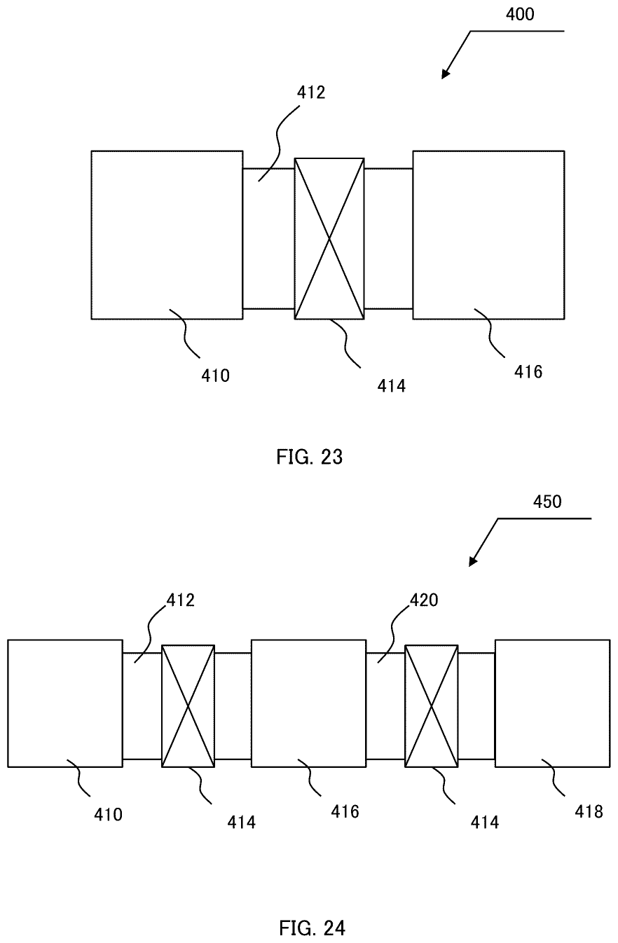

FIG. 23 shows a configuration example of a first manufacturing apparatus 400 according to the present embodiment. The first manufacturing apparatus 400 includes a first semiconductor layer forming apparatus 410, a first transport path 412, a gate valve 414, and a high-temperature heating furnace 416. The high-temperature heating furnace 416 may be referred to as an annealing apparatus. Although not shown in FIG. 23, it should be noted that the first manufacturing apparatus 400 may further include the first fixing stage 310, the second fixing stage 312, an etching apparatus, and a control part. Further, FIG. 23 omits detailed configurations of a preparation chamber for setting a substrate, a gas introduction facility, a heating stage, and the like, and shows only points of the configuration of the first manufacturing apparatus 400.

The first semiconductor layer forming apparatus 410 has a chamber for housing the first substrate 100, and forms the first semiconductor layer 120 having a predetermined thickness on the first substrate 100 in the chamber. In addition, the first semiconductor layer forming apparatus 410 forms the second semiconductor layer 160 on the first substrate 100. The first semiconductor layer forming apparatus 410 is a semiconductor crystal growth furnace for crystal-growing a semiconductor layer. The first semiconductor layer forming apparatus 410 can be an MOCVD furnace, for example.

The first semiconductor layer forming apparatus 410 is provided with an etching apparatus therein. The etching apparatus performs etching on the first surface 101 of the first substrate 100 fixed to the first fixing stage 310, to form a plurality of terrace portions 102 arranged in a first direction parallel to the horizontal plane of the first substrate 100, and a step portion 110 having a predetermined height between two adjacent terrace portions 102 in the first direction.

The high-temperature heating furnace 416 has a chamber for housing the first substrate 100. The high-temperature heating furnace 416 heats the first substrate 100 on which the first semiconductor layer 120 is formed, in the chamber, and vaporizes a portion of Si of the first substrate 100 from a part of the step portion 110 exposed from the first semiconductor layer 120, thereby forming the buffer layer 130 having graphene in at least a part between the first semiconductor layer 120 and the first substrate 100. The high-temperature heating furnace 416 is a furnace for performing high-temperature heat treatment at a temperature of 1300° C. or higher in an inert gas atmosphere, after the first semiconductor layer 120 has been formed on the surface of the first substrate 100. The high-temperature heating furnace 416 can be an RF heating furnace, for example.

The first transport path 412 connects the first semiconductor layer forming apparatus 410 and the high-temperature heating furnace 416. A substrate transport mechanism is provided to the chamber of the first semiconductor layer forming apparatus 410, the chamber of the high-temperature heating furnace 416, and the first transport path 412. The substrate transport mechanism allows the first substrate 100 fixed to the first fixing stage 310 to move between the chamber of the first semiconductor layer forming apparatus 410 and the chamber of the high-temperature heating furnace 416. Such a first transport path 412 is a transport path capable of transporting the first substrate 100 between the first semiconductor layer forming apparatus 410 and the high-temperature heating furnace 416 without exposing the first substrate 100 to the air.

The gate valve 414 is a valve capable of, depending on processes of semiconductor crystal growth and high-temperature heat treatment, blocking the flow of gas between the first semiconductor layer forming apparatus 410 and the high-temperature heating furnace 416 in each process.

The first fixing stage 310 fixes the first substrate 100 thereto. For example, the first fixing stage 310 exposes the first surface 101 of the first substrate 100 and fixes the second surface, which is on the opposite side from the first surface 101, thereto. The first fixing stage 310 is configured to be movable in and between the chamber of the first semiconductor layer forming apparatus 410 and the chamber of the high-temperature heating furnace 416, through the first transport path 412 with the first substrate 100 fixed thereto. The first fixing stage 310 may be a stage that is similar to the fixing stage described with reference to FIGS. 20A and 20B, or may be a different stage.

The control part controls the first fixing stage 310, the etching apparatus, the first semiconductor layer forming apparatus 410, and the high-temperature heating furnace 416. The control part executes the operation flow shown in FIG. 1. The control part has a function of causing the first fixing stage 310 to which the first substrate 100 is fixed to be moved, and a function of causing the plurality of terrace portions 102 and the step portion 110 to be formed on the first substrate 100; causing the first semiconductor layer 120 to be formed such that a part of the step portion 110 is exposed; and causing the buffer layer 130 to be formed after the first semiconductor layer 120 has been formed, for example. The control part may have a function of causing the second semiconductor layer 160 to be formed on the upper surface of the first semiconductor layer 120 formed on the upper surface of the formed buffer layer 130.

The control part includes a central processing unit (CPU) and a storage part, for example. The CPU functions as the control part that controls the first fixing stage 310, the etching apparatus, the first semiconductor layer forming apparatus 410, and the high-temperature heating furnace 416 by executing a program stored in the storage part.

The above-described first manufacturing apparatus 400 can execute the steps from forming a step in the first substrate 100 to forming the second semiconductor layer 160 directly above the first substrate 100 without exposing the first substrate 100 to the air. Therefore, it is possible to grow the second semiconductor layer 160 with higher quality since the first manufacturing apparatus 400 can maintain cleanliness of the surface of the first substrate 100.

FIG. 24 shows a configuration example of a second manufacturing apparatus 450 according to the present embodiment. In the second manufacturing apparatus 450, substantially the same operations as those of the first manufacturing apparatus 400 according to the present embodiment shown in FIG. 23 are denoted by the same reference numerals, and duplicate descriptions thereof are omitted. The second manufacturing apparatus 450 further includes a second semiconductor layer forming apparatus 418 and a second transport path 420.

The first semiconductor layer forming apparatus 410 of the second manufacturing apparatus 450 forms the first semiconductor layer 120 having a predetermined thickness on the first substrate 100. Then, the second semiconductor layer forming apparatus 418 forms the second semiconductor layer 160 having a predetermined thickness on the first substrate 100. The second semiconductor layer forming apparatus 418 may form the second semiconductor layer 160 in a different manner than the first semiconductor layer forming apparatus 410. The second semiconductor layer forming apparatus 418 can be an HVPE furnace, for example.

The second transport path 420 connects a chamber for housing the first substrate 100 of the second semiconductor layer forming apparatus 418 and a chamber for housing the first substrate 100 of the high-temperature heating furnace 416. Further, the first fixing stage 310 is provided such that it can further move between the chamber of the second semiconductor layer forming apparatus 418 and the chamber of the high-temperature heating furnace 416 with the first substrate 100 fixed thereto. The second transport path 420 may include a transport mechanism for moving and fixing the first substrate 100 fixed to the first fixing stage inside the high-temperature heating furnace 416 to the inside of the second semiconductor layer forming apparatus 418.

Accordingly, the control part has a function of controlling the second semiconductor layer forming apparatus 418, after causing the buffer layer 130 to be formed on the first substrate 100, to form the second semiconductor layer 160 on the upper surface of the first semiconductor layer 120 formed on the upper surface of the formed buffer layer 130.

In a similar manner as the first manufacturing apparatus 400, the above-described second manufacturing apparatus 450 can also execute the steps from forming a step in the first substrate 100 to forming the second semiconductor layer 160 in the first substrate 100 without exposing the first substrate 100 to the air. Therefore, it is possible to grow the second semiconductor layer 160 with higher quality since the first manufacturing apparatus 400 can maintain cleanliness of the surface of the first substrate 100.

The first manufacturing apparatus 400 and the second manufacturing apparatus 450 described above may further include a second fixing stage 312 that fixes thereto the surface of the first substrate 100 on the side opposite the surface where the second semiconductor layer 160 is formed on the first substrate 100. In this case, as described with reference to FIGS. 20A and 20B, the control part may have a function of controlling the first fixing stage 310 and the second fixing stage 312, after the second semiconductor layer 160 has been formed on the first substrate 100, to separate a partial region including the formed second semiconductor layer 160 from the first substrate 100. This enables the first manufacturing apparatus 400 and the second manufacturing apparatus 450 to perform the steps up to the step of separating the first substrate 100.

In the above-described first manufacturing apparatus 400 and second manufacturing apparatus 450 according to the present embodiment, the control part causes the first semiconductor layer 120 to be formed within a predetermined first temperature range that is higher than room temperature. The first temperature range is between 1000° C. and 1200° C., for example. The control part may have a function of causing the buffer layer 130 to be formed by performing heat treatment at a predetermined temperature that is higher than the predetermined first temperature range without reducing the temperature to room temperature after the first semiconductor layer 120 has been formed. The predetermined temperature is a preset temperature of 1300° C. or more, for example.

Further, the control part may have a function of causing the second semiconductor layer 160 to be formed in a predetermined second temperature range that is higher than room temperature without reducing the substrate temperature of the first substrate 100 to room temperature after the buffer layer 130 has been formed. The second temperature range is a range from 1000° C. to a preset temperature of 1300° C. or more, for example. This enables the first manufacturing apparatus 400 and the second manufacturing apparatus 450 to form the second semiconductor layer 160 on the first substrate 100 without reducing the substrate temperature of the first substrate 100 to room temperature, after forming the first semiconductor layer 120 on the first substrate 100.

Reducing the substrate temperature generates stress due to a difference in thermal expansion coefficients in the substrate. Misfit dislocations generated by a lattice mismatch in the region near the epitaxial growth interface between the first semiconductor layer 120 and the second semiconductor layer 160 may react with each other in the second semiconductor layer 160, due to stress caused by the difference in the thermal expansion coefficients at the time of reduction in the substrate temperature, which may generate a threading dislocation reaching the surface of the second semiconductor layer 160 (the surface on the opposite side from the first substrate 100 side). Since the first manufacturing apparatus 400 and the second manufacturing apparatus 450 can form the second semiconductor layer 160 on the first substrate 100 without reducing the substrate temperature of the first substrate 100 to room temperature, it is possible to prevent such threading dislocation generation in the second semiconductor layer 160, and to form a high-quality second semiconductor layer 160 with fewer defects.

The present disclosure is explained on the basis of the exemplary embodiments. The technical scope of the present disclosure is not limited to the scope explained in the above embodiments and it is possible to make various changes and modifications within the scope of the invention. For example, all or part of the apparatus can be configured with any unit which is functionally or physically dispersed or integrated. Further, new exemplary embodiments generated by arbitrary combinations of them are included in the exemplary embodiments of the present invention. Further, effects of the new exemplary embodiments brought by the combinations also have the effects of the original exemplary embodiments.

What is claimed is:

1. A semiconductor substrate manufacturing method comprising the steps of:
forming, on a first surface of a first substrate formed by cutting out a semiconductor crystal along a plane that is inclined with respect to a horizontal plane orthogonal to a crystal growth direction of the semiconductor crystal containing at least Si and C, a plurality of terrace portions that are surfaces along a first direction parallel to the horizontal plane of the first substrate, and a step portion having a predetermined height and positioned between two adjacent terrace portions in the first direction;
depositing a first semiconductor layer having a critical film thickness or more after the terrace portions and the step portion have been formed on the first surface of the first substrate, thereby forming the first semiconductor layer such that a part of the step portion is exposed; and
vaporizing a portion of Si of the first substrate from a part of the step portion exposed from the first semiconductor layer by performing heat treatment on the first substrate on which the first semiconductor layer is formed, thereby forming a buffer layer having at least one graphene layer in at least a part between the first semiconductor layer and the first substrate, wherein
a predetermined height of the step portion is larger than a critical film thickness of the first semiconductor layer obtained by growing crystals on the first surface of the first substrate.

2. The semiconductor substrate manufacturing method according to claim 1, wherein
the forming the plurality of terrace portions and the step portion forms the terrace portions and the step portion on the first surface of the first substrate by etching the first surface of the first substrate in a hydrogen gas atmosphere.

3. The semiconductor substrate manufacturing method according to claim 1, wherein
the semiconductor crystal is an SiC single crystal,
the horizontal plane orthogonal to the crystal growth direction of the semiconductor crystal is a (0001) plane, and
the first surface of the first substrate is inclined with respect to the horizontal plane in a range of an angle that is greater than 0° and less than 10°.

4. The semiconductor substrate manufacturing method according to claim 1, wherein
the forming the first semiconductor layer forms the first semiconductor layer by depositing a semiconductor having a thickness that is equal to or less than a height of the step portion on the first surface of the first substrate.

5. The semiconductor substrate manufacturing method according to claim 1, wherein
the height of the step portion is 5 nm or more and 200 nm or less.

6. The semiconductor substrate manufacturing method according to claim 1, wherein
a difference between a lattice constant of the first substrate and a lattice constant of the first semiconductor layer is 4% or less.

7. The semiconductor substrate manufacturing method according to claim 1, further comprising the step of:
forming a second semiconductor layer on an upper surface of the first semiconductor layer after the forming the buffer layer.

8. The semiconductor substrate manufacturing method according to claim 7, wherein
the second semiconductor layer includes at least one of a single-element semiconductor material, a group III-V nitride semiconductor material, or a group II-VI compound semiconductor material.

9. The semiconductor substrate manufacturing method according to claim 7, wherein
the forming the buffer layer vaporizes at least a part of the first semiconductor layer by performing heat treatment on the first substrate, and forms a region where the buffer layer and the second semiconductor layer are in contact with each other, or a region where the first substrate and the second semiconductor layer are in contact with each other.

10. The semiconductor substrate manufacturing method according to claim 7, further comprising the step of:
separating at least a partial region including the second semiconductor layer from the first substrate, thereby forming a second substrate including the second semiconductor layer, after forming the second semiconductor layer.

11. The semiconductor substrate manufacturing method according to claim 10, wherein
the forming the second substrate further includes forming a predetermined device in and on the second semiconductor layer after forming the second semiconductor layer.

12. The semiconductor substrate manufacturing method according to claim 10, further comprising the step of:
bonding the second substrate to a third substrate after forming the second substrate.

13. The semiconductor substrate manufacturing method according to claim 7, wherein
the forming the first semiconductor layer forms the first semiconductor layer within a predetermined first temperature range that is higher than room temperature,
the forming the buffer layer forms the buffer layer by performing heat treatment at a temperature that is higher than the predetermined first temperature range without reducing the temperature to the room temperature after forming the first semiconductor layer, and
the forming the second semiconductor layer forms the second semiconductor layer within a predetermined second temperature range that is higher than the room temperature without reducing the temperature to the room temperature after forming the buffer layer.

14. A semiconductor substrate, comprising:
a first substrate formed of a semiconductor crystal containing at least Si and C, and including, on a first surface, a plurality of terrace portions that are surfaces along a first direction parallel to a horizontal plane perpendicular to a crystal growth direction of the semiconductor crystal, and a step portion having a predetermined height provided between two adjacent terrace portions in the first direction,
a first semiconductor layer formed to have a thickness that is less than a height of the step portion and is equal to or greater than a critical film thickness on the plurality of terrace portions, in at least a part of a surface of the first substrate on which the plurality of terrace portions are formed, and
a buffer layer having at least one graphene layer formed in at least a part between the first semiconductor layer and the first substrate, wherein
a predetermined height of the step portion is larger than a critical film thickness of the first semiconductor layer obtained by growing crystals on the first surface of the first substrate.

15. The semiconductor substrate according to claim 14, further comprising:
a second semiconductor layer formed on a surface of the first semiconductor layer on an opposite side from the first substrate.

16. The semiconductor substrate according to claim 15, wherein
a region where the buffer layer and the second semiconductor layer are in contact with each other, or a region where the first substrate and the second semiconductor layer are in contact with each other is formed.

17. A semiconductor substrate manufacturing apparatus, comprising:
a first fixing stage that exposes a first surface of a first substrate formed by cutting out a semiconductor crystal containing at least Si and C along a plane that is inclined with respect to a horizontal plane perpendicular to a crystal growth direction of the semiconductor crystal, and fixes thereto a second surface that is on an opposite side from the first surface;
an etching apparatus that etches the first surface of the first substrate fixed to the first fixing stage to form a plurality of terrace portions that are surfaces along a first direction parallel to the horizontal plane of the first substrate, and a step portion having a predetermined height and positioned between two adjacent terrace portions in the first direction;
a first semiconductor layer forming apparatus for forming a first semiconductor layer having a critical film thickness or more on the first surface of the first substrate;
an annealing apparatus for heating the first substrate on which the first semiconductor layer is formed and vaporizing a portion of Si of the first substrate from a part of the step portion exposed from the first semiconductor layer, thereby forming a buffer layer having at least one graphene layer in at least a part between the first semiconductor layer and the first substrate;
a first transport path that connects a chamber for housing the first substrate of the first semiconductor layer forming apparatus and a chamber for housing the first substrate of the annealing apparatus; and
a control part that controls the first fixing stage, the etching apparatus, the first semiconductor layer forming apparatus, and the annealing apparatus, wherein
a substrate transport mechanism is provided in the chamber for housing the first substrate of the first semiconductor layer forming apparatus; the chamber for housing the first substrate of the annealing apparatus; and the first transport path, and the substrate transport mechanism allows the first substrate fixed to the first fixing stage to be movable between the chamber of the first semiconductor layer forming apparatus and the chamber of the annealing apparatus,
the etching apparatus is provided inside the first semiconductor layer forming apparatus,
the control part at least has a function of controlling steps of: moving the first substrate from the first fixing stage to which the first substrate is fixed; forming the plurality of terrace portions and the step portion on the first substrate; forming the first semiconductor layer such that a part of the step portion is exposed; and forming the buffer layer after the forming the first semiconductor layer, and
a predetermined height of the step portion is larger than a critical film thickness of the first semiconductor layer obtained by growing crystals on the first surface of the first substrate.

18. The semiconductor substrate manufacturing apparatus according to claim 17, wherein
the first semiconductor layer forming apparatus can form a second semiconductor layer on a first surface side of the first substrate after the buffer layer has been formed, and
the control part further has a function of controlling a step of forming the second semiconductor layer on the first surface side of the first substrate after the buffer layer has been formed.

19. The semiconductor substrate manufacturing apparatus according to claim 17, comprising:
a second semiconductor layer forming apparatus for forming a second semiconductor layer on the first surface of the first substrate, and
a second transport path that connects a chamber for housing the first substrate of the second semiconductor layer forming apparatus and a chamber for housing the first substrate of the annealing apparatus, wherein
a transport mechanism is provided in the chamber for housing the first substrate of the second semiconductor layer forming apparatus; the chamber for housing the first substrate of the annealing apparatus; and the second transport path, and the transport mechanism allows the first substrate fixed to the first fixing stage to be movable between the chamber of the second semiconductor layer forming apparatus and the chamber of the annealing apparatus, and
the control part further has a function of controlling a step of forming the second semiconductor layer on a first surface side of the first substrate by controlling the second semiconductor layer forming apparatus after the buffer layer has been formed.

20. The semiconductor substrate manufacturing apparatus according to claim 18, further comprising:
a second fixing stage that fixes thereto a surface of the second semiconductor layer formed on the first substrate that is on an opposite side from the first substrate, wherein
the control part further has a function of controlling a step of separating at least a partial region including the formed second semiconductor layer from the first substrate by controlling the first fixing stage and the second fixing stage after the second semiconductor layer has been formed on the first substrate.

21. The semiconductor substrate manufacturing apparatus according to claim 18, wherein
the control part further has a function of controlling steps of.
forming the first semiconductor layer within a predetermined first temperature range that is higher than room temperature,
forming the buffer layer by performing heat treatment at a temperature that is higher than the predetermined first temperature range without reducing the temperature to the room temperature after the first semiconductor layer has been formed, and
forming the second semiconductor layer in a predetermined second temperature range that is higher than the room temperature without reducing the temperature to the room temperature after the buffer layer has been formed.
